(19) United States
(12) Patent Application Publication
(10) Pub. No.: US 2023/0089230 A1
(43) Pub. Date: Mar. 23, 2023

(54) BaseLine Restoration Circuit

(71) Applicant: Becton, Dickinson and Company, Franklin Lakes, NJ (US)

(72) Inventor: Vitali Souchkov, Pinole, CA (US)

(21) Appl. No.: 17/897,838

(22) Filed: Aug. 29, 2022

Related U.S. Application Data
(60) Provisional application No. 63/246,395, filed on Sep. 21, 2021.

(51) Int. Cl. H03F 3/45; G01N 15/14

(52) U.S. Cl. CPC H03F 3/45475; G01N 15/1459; H03F 2200/165; H03F 2200/372; G01N 2015/1006

(57) ABSTRACT

Aspects of the present disclosure include circuits, systems and methods for baseline signal restoration over differential outputs. Circuits according to certain embodiments include an input module for receiving a signal from a sensor, an amplifier module, operably connected to the input module, for modifying the input signal, a baseline restoration module, operably connected to the amplifier module, for extracting a direct current component of the input signal, and an output module, operably connected to the amplifier module, for transmitting a baseline restored signal, wherein the output module comprises differential outputs. Baseline restoration systems according to certain embodiments include a baseline restoration circuit for generating a baseline restored signal on differential outputs, a downstream receiver circuit for receiving a baseline restored signal on differential inputs transmitted by the baseline restoration circuit, and cable core wires configured to connect the differential outputs of the baseline restoration circuit with the differential inputs of the downstream receiver circuit. Flow cytometry systems with baseline restoration using the subject circuits are described. Methods for baseline restoration are also provided.

### CROSS-REFERENCE TO RELATED APPLICATION

Pursuant to 35 U.S.C. § 119 (e), this application claims priority to the filing date of U.S. Provisional Patent Application Ser. No. 63/246,395 filed Sep. 21, 2021; the disclosure of which application is incorporated herein by reference in their entirety.

### INTRODUCTION

Electrical signals corresponding to sensor outputs are often used in connection with characterizing components of a sample (e.g., biological samples), for example when the sample is used in the diagnosis of a disease or medical condition. For example, when a sample is irradiated, light can be scattered by the sample, transmitted through the sample as well as emitted by the sample (e.g., by fluorescence), where such scattered, transmitted or emitted light is sensed by one or more light detectors and converted into corresponding electrical signals. Variations in the sample components, such as morphologies, absorptivity and the presence of fluorescent labels may cause variations in the light that is scattered, transmitted or emitted by the sample and, accordingly, variations in the corresponding electrical signals. These variations can be used for characterizing and identifying the presence of components in the sample. The amount of light that reaches the detector corresponding to such variations, and not to background light from light used to irradiate particles in the sample, can impact how effectively components of the sample are characterized and identified. Baseline restoration techniques refer to extracting and subtracting signals generated by background light and thermal carriers that reach the detector in order to prevent such signals from representing electrical data signals generated by sensors.

One technique that utilizes light detection to characterize the components in a sample is flow cytometry. Simultaneous readout of numerous light detection channels in flow cytometers is especially important for spectrometry applications. Changing temperature conditions at the detector locations add greater importance for baseline restoration, and using baseline restoration circuitry located close to the photodetector is quite beneficial for that purpose. In some cases, detection of a weak signal has to be done in the context of an intense background of a laser radiation (that eventually may slowly change intensity in time), where the direct current (DC) component is few orders of magnitude larger than the signal component. Compensating the DC component locally, i.e., close to the detector location enables a higher dynamic range for the useful signal transferred downstream to the acquisition system. In addition, very often an accurate transfer of the signal downstream necessitates conditioning of the signal into a differential form, making the downstream transmission less susceptible to certain environmental conditions such as electromagnetic interference (EMI), for example originating from other subsystems of a flow cytometer.

### SUMMARY

Aspects of the present disclosure include circuits, systems and methods for baseline signal restoration over differential outputs. Circuits according to certain embodiments include an input module for receiving a signal from a sensor, an amplifier module, operably connected to the input module, for modifying the input signal, a baseline restoration module, operably connected to the amplifier module, for extracting a direct current component of the input signal, and an output module, operably connected to the amplifier module, for transmitting a baseline restored signal, wherein the output module comprises differential outputs.

In some embodiments, the circuit is configured to subtract a direct current component of the input signal that varies slowly over time relative to a duration of the input signal. In some cases, the direct current component of the input signal varies slowly over time in part based on a temperature of the sensor generating the input signal.

In some embodiments, the circuit is configured to receive input signals corresponding to a plurality of events and to separate signals corresponding to each event. In certain embodiments, the circuit is configured so that a high-pass cutoff frequency of the circuit is below 1 Hz.

In some embodiments, the output module comprises a first differential output and a second differential output. In some cases, a difference between signals on the first and second differential outputs comprises the baseline restored signal. In certain cases, the difference between signals comprises a voltage difference between the first and second differential outputs. In some embodiments, the circuit is configured so that the differential outputs reduce sensitivity to low-frequency noise. In instances, the circuit is configured so that the differential outputs reduce sensitivity to noise caused by electromagnetic interference. In some cases, the first and second differential outputs are co-located to reduce sensitivity to electromagnetic interference, for example, the differential outputs may be connected to a twisted pair and/or the differential outputs are shielded to reduce sensitivity to electromagnetic interference and cross-talk. In some cases, the differential outputs comprise shielded cable core wires. In certain embodiments, the shielded cable core wires comprise a common shield among a plurality of differential outputs.

In some embodiments, the output module is configured to absorb reflections of signals transmitted at the differential outputs. In some cases, the output module comprises matched resistors operably connected to the differential outputs configured to absorb reflections of signals transmitted on the differential outputs.

In some embodiments, the circuit is configured to be located at proximity of the sensor. In some cases, the circuit is configured to be co-located with the sensor. In some cases, the circuit is configured to be located within 1 cm of the sensor. In other cases, the circuit is installed on a substrate, wherein the substrate is shaped such that the substrate is located proximally with the sensor. In instances, the substrate is a printed circuit board. In some embodiments, the sensor is a light detector. In some cases, the light detector is a photomultiplier tube or a photodiode or an avalanche photo detector.

In embodiments, the amplifier module comprises a first amplifier with differential amplifier outputs. In some cases, the amplifier module comprises a plurality of feedback loops between first amplifier outputs and inputs.

In embodiments, the baseline restoration module comprises a filter network operably connected to the differential amplifier outputs. In some embodiments, the filter network comprises a low-pass filter for extracting a direct current component of the input signal. In some cases, the low-pass filter comprises a first transconductance element and a capacitor. In instances, an output of the filter network is operably connected to an input of the amplifier module. In some instances, the output of the filter network is operably connected to an input of the first amplifier. In some instances, the output of the filter network is operably connected to a non-inverting input of the first amplifier. In embodiments, the baseline restoration module further comprises a second transconductance element operably connected to the first transconductance element and configured to convert a voltage-based signal to a current-based signal. In some embodiments, the baseline restoration network comprises a switch to disengage to the filter network from the circuit.

In embodiments, the input module is configured to transform the input signal received from the sensor. In some embodiments, the input signal received from the sensor is a current-based signal and the input module is configured to transform the current-based signal to a voltage-based signal. In other embodiments, the input module comprises a transistor. In instances, the input signal from the sensor is operably connected to a gate of the transistor.

In embodiments, the circuit is an analog circuit. In some embodiments, the circuit is a circuit of a light detection system. In some cases, the circuit is a circuit of a light detection system of a flow cytometer.

Aspects of the disclosure also include systems for generating, transmitting and receiving baseline restored signals over differential outputs. Systems according to certain embodiments include a baseline restoration circuit for generating a baseline restored signal on differential outputs such as a baseline restoration circuit as summarized above, a downstream receiver circuit for receiving a baseline restored signal on differential inputs transmitted by the baseline restoration circuit, and cable core wires configured to connect the differential outputs of the baseline restoration circuit with the differential inputs of the downstream receiver circuit. Certain systems are sensors readout systems. In embodiments, the downstream receiver circuit is configured to convert differential signals received from the baseline restoration circuit into digital signals.

In embodiments, the downstream receiver circuit includes an anti-alias filter module operably connected to the differential inputs, a kickback protection module operably connected to the output of the anti-alias filter module and an analog-to-digital converter module operably connected to the output of the kickback protection module for converting signals received from the baseline restoration circuit into digital signals. In some embodiments, the analog to digital converter module comprises differential inputs. In some cases, the anti-alias filter module comprises an amplifier with differential inputs and differential outputs. In certain cases, the anti-alias filter amplifier comprises a plurality of feedback paths between amplifier outputs and inputs. In embodiments, the anti-alias filter amplifier comprises a network of resistors and capacitors. In other embodiments, the anti-alias filter module is configured to receive two differential offset control voltages as additional inputs. In certain embodiments, the kickback protection module comprises a network of resistors and capacitors.

In embodiments, the downstream receiver circuit further comprises a voltage source module configured to generate a high voltage control potential signal for a sensor. In some cases, the high voltage control potential signal comprises a sensor gain setting for a light detector. In some embodiments, the light detector is an avalanche photodiode sensor or a photodiode sensor or a photomultiplier tube sensor. In other embodiments, the voltage source module comprises a DC-to-DC converter. In some cases, the voltage source module comprises a feedback network configured to compare the high voltage control potential signal with a reference voltage.

In some embodiments, the voltage source module comprises a digital-to-analog converter operably connected to the output of the DC-to-DC converter and configured to output the high voltage control potential signal for transmission to a sensor and offset control voltages for the anti-alias filter. In other embodiments, the cable core wires further comprise a high voltage transmission line configured to the high voltage control potential signal to a sensor. In some cases, the sensor is co-located with the baseline restoration circuit.

Aspects of the disclosure also include flow cytometry systems that include systems for generating, transmitting and receiving baseline restored signals over differential outputs. Flow cytometry systems according to certain embodiments include a light source configured to irradiate a sample comprising particles flowing in a flow stream, a light detection system comprising a light sensor for detecting light from the particles in the sample and generating a data signal based on the detected light, and a sensors readout system such as a sensors readout system summarized above.

In embodiments of the flow cytometer system, the baseline restoration circuit is located proximally to the light detection system. In some embodiments, the baseline restoration circuit is located remotely from the downstream receiver circuit. In some cases, the downstream receiver circuit generates a high voltage control potential signal for the light sensor. In certain embodiments of the flow cytometer system, the high voltage control potential signal comprises a gain setting for the light sensor. In other embodiments, the high voltage control potential signal is transmitted to the light detection system via the cable core wires, wherein the cable core wires are operably connected to the downstream receiver circuit and the light detection system. In certain embodiments, the system further comprises processing the data signal detected by the light sensor remotely from the light detection system. In some cases, processing the data signal detected by the light sensor comprises converting the data signal into a digital signal.

Aspects of the disclosure also include methods for generating a baseline restored signal over differential outputs by a baseline restoration circuit. Embodiments of the methods comprise receiving by the circuit an input signal originating from a sensor, generating by the circuit based a differential signal based on the input signal, extracting a direct current component of the differential signal, subtracting the extracted direct current component of the differential signal to generate a baseline restored signal, and outputting the resulting baseline restored signal over differential outputs.

In embodiments, the method is applied continuously to subtract the direct current component of the input signal that may vary slowly over time. In other embodiments, the direct current component varies slowly over time in part based on a temperature of a sensor generating the input signal. In some cases, generating by the circuit a differential signal based on the input signal comprises applying an amplifier configured to generate differential output signals.

In embodiments of the method, extracting a direct current component of the differential signal comprises applying a filter network to the differential signal. In other embodiments, the filter network comprises a low pass filter. In certain embodiments, the filter network comprises a transconductance element and a capacitor. In some cases, subtracting the extracted direct current component of the differential signal comprises feeding the extracted direct current component of the differential signal into a circuit feedback loop. In other cases, feeding the extracted direct current component of the differential signal into a circuit feedback loop comprises feeding the output of an amplifier for generating a differential output signal into an input of the amplifier. In embodiments, the input of the amplifier is a non-inverting input of the amplifier.

In embodiments, outputting the resulting baseline restored signal over differential outputs comprises transmitting the baseline restored signal over cable core wires. In some cases, the cable core wires are twisted pair wires. In some cases, the cable core wires are shielded.

Aspects of the disclosure also include methods for generating, transmitting and receiving a baseline restored signal over differential outputs. Embodiments of the methods comprise generating by a sensor an input signal, deploying a sensors readout system, such as the sensors readout systems summarized above, operably connected to the sensor, applying the baseline restoration circuit of the sensors readout system to the input signal to generate a baseline restored differential signal, transmitting by the baseline restoration circuit the baseline restored differential signal over the cable core wires, and receiving by the downstream receiver circuit over the cable core wires the baseline restored differential signal.

Embodiments of such methods further include converting by the downstream receiver circuit the baseline restored differential signal into a digital signal. Other embodiments further comprise processing the digital signal to identify events detected by the sensor. Other embodiments further comprise generating by the downstream receiver circuit a high voltage control potential. Other embodiments further comprise transmitting the high voltage control potential over cable core wires to a sensor for sensor gain control.

### BRIEF DESCRIPTION OF THE FIGURES

The invention may be best understood from the following detailed description when read in conjunction with the accompanying drawings. Included in the drawings are the following figures:

FIGS. 1A-1B depict a baseline restoration circuit with differential outputs according to certain embodiments.

FIGS. 2A-2B depict a baseline restoration circuit with differential outputs according to certain other embodiments.

FIGS. 3A-3B depict a downstream receiver circuit with differential inputs according to certain embodiments.

FIG. 4A depicts a functional block diagram of a particle analysis system according to certain embodiments. FIG. 4B depicts a flow cytometer according to certain embodiments.

FIG. 5 depicts a functional block diagram for one example of a particle analyzer control system according to certain embodiments.

FIG. 6A depicts a schematic drawing of a particle sorter system according to certain embodiments.

FIG. 6B depicts a schematic drawing of a particle sorter system according to certain embodiments.

FIGS. 7A-7B depict pictures of aspects of a baseline restoration circuit with differential outputs according to certain embodiments.

FIGS. 8A-8B depict another view of aspects of a baseline restoration circuit with differential outputs for use with photodiode sensors according to certain embodiments.

FIGS. 9A-9B depict another view of aspects of a baseline restoration circuit with differential outputs for use with APD sensors according to certain embodiments.

FIG. 10 shows simulation results in connection with an embodiment of a downstream receiver circuit.

FIG. 11 depicts one embodiment of a sensors readout system implemented in the context of a flow cytometer readout with 16 sensors according to certain embodiments.

FIG. 12 depicts an embodiment of a front-end board for reading out the APDs that corresponds to a front-end baseline restoration circuit.

FIG. 13 depicts measured results of an embodiment of a front-end board for reading out APDs corresponding to a front-end baseline restoration circuit.

FIG. 14 shows measured results of amplitude distributions of embodiments when no signal is present.

FIG. 15 shows certain results of equivalent noise current measurements.

FIG. 16 shows embodiments of sensor readout systems according to certain embodiments.

### DETAILED DESCRIPTION

Aspects of the present disclosure include circuits, systems and methods for baseline signal restoration over differential outputs. Circuits according to certain embodiments include an input module for receiving a signal from a sensor, an amplifier module, operably connected to the input module, for modifying the input signal, a baseline restoration module, operably connected to the amplifier module, for extracting a direct current component of the input signal, and an output module, operably connected to the amplifier module, for transmitting a baseline restored signal, wherein the output module comprises differential outputs. Systems according to certain embodiments include a baseline restoration circuit for generating a baseline restored signal on differential outputs, such as a baseline restoration circuit as summarized above, a downstream receiver circuit for receiving a baseline restored signal on differential inputs transmitted by the baseline restoration circuit, and cable core wires configured to connect the differential outputs of the baseline restoration circuit with the differential inputs of the downstream receiver circuit.

Flow cytometry systems according to certain embodiments include a light source configured to irradiate a sample comprising particles flowing in a flow stream, a light detection system comprising a light sensor for detecting light from the particles in the sample and generating a data signal based on the detected light, and a sensors readout system such as a sensors readout system summarized above. Methods for generating a baseline restored signal over differential outputs by a baseline restoration circuit are also described. Methods for generating, transmitting and receiving a baseline restored signal over differential outputs are also provided.

Before the present invention is described in greater detail, it is to be understood that this invention is not limited to particular embodiments described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

Certain ranges are presented herein with numerical values being preceded by the term “about.” The term “about” is used herein to provide literal support for the exact number that it precedes, as well as a number that is near to or approximately the number that the term precedes. In determining whether a number is near to or approximately a specifically recited number, the near or approximating unrecited number may be a number which, in the context in which it is presented, provides the substantial equivalent of the specifically recited number.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, representative illustrative methods and materials are now described.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present invention is not entitled to antedate such publication by virtue of prior invention. Further, the dates of publication provided may be different from the actual publication dates which may need to be independently confirmed.

It is noted that, as used herein and in the appended claims, the singular forms “a”, “an”, and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention. Any recited method can be carried out in the order of events recited or in any other order which is logically possible.

While the apparatus and method has or will be described for the sake of grammatical fluidity with functional explanations, it is to be expressly understood that the claims, unless expressly formulated under 35 U.S.C. § 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 U.S.C. § 112 are to be accorded full statutory equivalents under 35 U.S.C. § 112.

As summarized above, the present disclosure provides circuits and systems for baseline signal restoration over differential outputs. In further describing embodiments of the disclosure, circuits having an input module for receiving a signal from a sensor, an amplifier module, operably connected to the input module, for modifying the input signal, a baseline restoration module, operably connected to the amplifier module, for extracting a direct current component of the input signal, and an output module, operably connected to the amplifier module, for transmitting a baseline restored signal, wherein the output module comprises differential outputs are first described in greater detail. Next, systems, including flow cytometry systems, for generating, transmitting and receiving baseline restored signals with differential outputs are described. Methods for generating baseline restored signals over differential outputs, as well as methods for generating, transmitting and receiving baseline restored signals over differential outputs are described.

### Circuits for Baseline Restoration Over Differential Outputs

Aspects of the present disclosure include circuits for baseline signal restoration over differential outputs. Circuits according to certain embodiments include an input module for receiving a signal from a sensor, an amplifier module, operably connected to the input module, for modifying the input signal, a baseline restoration module, operably connected to the amplifier module, for extracting a direct current component of the input signal, and an output module, operably connected to the amplifier module, for transmitting a baseline restored signal, wherein the output module comprises differential outputs. In embodiments, the circuit is an analog circuit, meaning the signals manipulated by the circuit are continuously variable, not at discrete levels. As described in detail below, the circuit may comprise a part of a light detection system, i.e., the circuit may be part of a light sensor. In some cases, the circuit comprises part of a light detection system of a flow cytometer.

By “baseline restoration,” it is meant subtracting or removing or reducing a direct current (DC) component of a signal, such as an electrical signal. Electrical signals of interest include electrical signals generated by sensors, such as light detectors, as described in detail below. Electrical signals may refer to voltage-based or current-based signals or combinations thereof and are not limited thereto. A DC component of an input signal originating from a sensor may arise from the sensor being exposed to a background of laser radiation, i.e., laser light in the context of flow cytometry, for example. In embodiments, such exposure to background laser light does not reflect desired information corresponding to underlying measurements of data, i.e., a data signal component of the input signal, and furthermore can hinder the collection of the data signal of interest. Subtracting or removing or reducing a DC component of an input signal results in isolating other components of the input signal, i.e., isolating the data signal, also referred to as the baseline restored signal. For example, in the context of flow cytometry, isolating the data signal may refer to isolating a data signal corresponding to underlying measurements of data, such as the detection of events corresponding to particles in a flow stream. In embodiments, the direct current component of an input signal may be orders of magnitude greater than the data signal component of the input signal and moreover may change over time, for example, may vary slowly over time relative to the duration of the input signal of interest. That is, the data signal may be a “weak signal” in the context of a “bright channel” background, and furthermore, the “bright channel” background may change slowly over time.

Embodiments of the circuit may be configured to subtract a direct current component of the input signal that varies slowly over time relative to a duration of the input signal. That is, the DC component of the input signal may change over time, such as increasing or decreasing or combinations of increasing and decreasing over time. By “varying slowly over time,” it is meant that the change in the background direct current component of an input signal may change slowly relative to the duration of the data signal component of the input signal, i.e., the input signal of interest, such as, in the context of flow cytometry, the duration of a data signal corresponding to a particle in a flow stream. In some cases, the direct current component of the input signal may vary by 0.1% or less over the duration of the input signal of interest, i.e., the data signal corresponding to an “event.” That is, the direct current component may increase or decrease by 0.1% or less during the time the input signal of interest is measured, e.g., during the time a signal is generated based on a particle in a flow stream, in the context of flow cytometry.

Such changes may be a result of changing conditions of the sensor. For example, the DC component of the input signal may change based on changes in the sensor temperature. As described above, the DC component of an input signal may change slowly, i.e., slowly relative to the number of expected events, i.e., desired data signals expected to occur, before a temperature change, or in other cases may change quickly. Embodiments of the circuit may be configured to subtract or reduce a direct current component of the input signal where the direct current component of the input signal changes over time in part based on a temperature of the sensor generating the input signal.

In some embodiments, the circuit is configured to receive input signals corresponding to a plurality of events and to separate signals corresponding to each event. In some embodiments, the circuit is configured so that a high-pass cut off frequency of the circuit is configured to separate signals corresponding to each event. By “high-pass cutoff frequency,” it is meant that the circuit is configured to act as a filter by allowing high frequency signals and blocking or attenuating or reducing the gain of low frequency signals. That is, the circuit may be configured such that a separated or extracted signal from the amplifier output is low passed with the filter and applied back to the input through feedback, thus creating a high pass transfer function for the overall circuit.

In some cases, circuits are configured to separate signals corresponding to each event by configuring the cutoff frequency of the circuit as desired, such as, for example, 1 Hz or less. In some cases, the high-pass cutoff frequency may be 10 Hz, or less or 100 Hz or less, or 1,000 Hz or less. The cutoff frequency of the circuit refers to the frequency at which low frequency signals are attenuated by a specified amount. In some cases, the cutoff frequency of the high pass filter is configured to be 1 Hz.

By “events,” it is meant data signals, i.e., the component of an input signal corresponding to a signal of interest. For example, in the context of flow cytometry, data signals, or input signal of interest, corresponding to events may correspond to signals received in connection with a particle flowing in a flow stream through an interrogation region of a flow cytometer, thereby generating an input signal. By “separating signals corresponding to each event,” it is meant that, in the context of flow cytometry, implementing the baseline restoration circuit creates a low frequency cutoff, and the lower the frequency of this cutoff the smaller the impact of the “tails” of preceding events to the data signal. That is, separating signals corresponding to each event, in the context of flow cytometry, may comprise reducing the effect of, i.e., attenuating, tails of input signals, such as signal tails that extend in time to overlap with a subsequent input signal.

### Differential Outputs:

As described above, embodiments of the circuit comprise an output module with differential outputs. By “differential outputs,” it is meant that the circuit comprises a plurality of outputs configured such that a signal of interest, such as the data signal or baseline restored signal, as described above, is represented as the difference between the signals transmitted on the plurality of outputs. That is, for example, the data signal is not transmitted on a single signal output with a constant ground reference. Instead, for example, the baseline restored signal may be represented as a difference between two or more signals, such as the difference between two signals on two differential outputs. In some cases, each of the plurality of signals are dynamic, i.e., are not a constant ground. In some embodiments, the output module comprises a first differential output and a second differential output. That is, in some embodiments, the baseline restored signal comprises a difference in the signals transmitted on each of the first and second differential outputs. In embodiments, the baseline restored signal is a difference in the voltages at which the first and second differential outputs are driven.

In embodiments, the circuits are configured so that the differential outputs reduce sensitivity to low-frequency noise, such as noise caused by electromagnetic interference or background electromagnetic radiation. In embodiments, the differential outputs are co-located to reduce sensitivity to electromagnetic interference. For example, the differential outputs may be co-located for a preponderance of the distance the signals are transmitted, such as, for example, from a region of a system dedicated to the sensor to a region of the system dedicated to signal processing. Such distances may vary based on the mechanical configuration and requirements of the underlying system and may range from 1 cm or more, such as 10 cm or 50 cm or 1 m or 2 m. By “co-located,” it is mean that the first and second differential outputs are located with 1 cm or less of each other, such as within 0.5 cm or less or 0.1 cm or less. In some cases, co-located differential outputs are connected to a twisted pair. Co-locating differential outputs helps ensure that any electromagnetic interference effects signals transmitted on each differential output in the same way and to the same extent such that the difference between the differential signals remains unchanged, even when both differential signals are affected by, for example, electromagnetic interference.

In other embodiments, the differential outputs are shielded to reduce sensitivity to electromagnetic interference and cross-talk, such as for example, using shielded cable core wires for the differential outputs. By “cross-talk,” it is meant interference caused by signals transmitted on one differential pair effecting signals transmitted on a separate differential pair. Any convenient commercially available cable core wires may be applied. By “shielding,” it is meant positioning the differential outputs within a single outer layer of a conductor such that the differential outputs are surrounded by the outer conductor. The outer conductor—i.e., the shield—works to reflect electromagnetic interference or conduct it to ground, in either case, absorbing the effect of electromagnetic radiation such that the differential outputs are not affected. In some embodiments, a plurality of sensors and baseline restoration circuits may be located proximally among themselves and remotely from signal processing circuitry. In such cases, multiple differential signals (comprising multiple baseline restored signals) are transmitted over multiple pairs of differential outputs. In embodiments where this is the case, the shielded cable core wires may comprise a common shield among a plurality of differential outputs.

As described above, the output module comprises differential outputs, in embodiments. The output module transmits differential output signals across the differential outputs. In some cases, the transmission of the differential output signals on the differential outputs results in an amount of reflection of the differential signals at the receiver circuit impedances. In certain embodiments, the output module is configured to absorb reflections of signals transmitted at the differential outputs. For example, the output module may comprise matched resistors operably connected to the differential outputs configured to absorb reflections of signals transmitted on the differential outputs. That is, each of the first differential output and the second differential output, as described above, may comprise a resistor attached in series with the differential output and the ultimate receiver of the differential signal. Any commercially available resistor may be applied, such as resistors available through Texas Instruments or Radio Shack or similar electronic component outlets, or such as fixed resistance resistors or resistors integrated into a substrate such as a printed circuit board.

In embodiments, the resistances of the resistors attached to the differential outputs may be chosen to match the impedance of the cable characteristic impedance (i.e., the impedance of the transmission lines). Any convenient resistances may be applied and may vary depending on, for example, the impedance of the transmission lines used to transmit the differential outputs. In embodiments, resistors may be selected with resistance values of 1 Ohms or more, such as 10 Ohms or 25 Ohms or 50 Ohms or 100 Ohms or more. Resistors may be selected with a tolerance of 1% or less, such as 0.1% or 0.01% or less.

### Circuit Location Relative to Sensor:

In embodiments, the circuit is configured to be located at proximity of the sensor. By locating the circuit at proximity of the sensor, the circuit and the sensor are configured such that a baseline restored signal is generated without having to transmit the sensor input signal, in some cases, nearly immediately upon generation of the input signal by the sensor. Generating the baseline restored signal prior to transmitting the input signal downstream to additional circuitry, such as signal processing circuitry, not located proximally with the sensor, increases the dynamic range available to the data signal. By locating the circuit “at proximity of” the sensor, it is meant that the input signal generated by the sensor is transmitted 1 cm or less, such as 0.75 cm or 0.5 cm or 0.25 cm, over wires before arriving at the circuit, such as less than 1 cm or less than 1 mm. In some cases, the circuit is configured to be co-located with the sensor, such as, in some cases, integrated into the sensor. In some cases, the circuit is installed on a substrate, such as a printed circuit board, that is shaped so that it can be located proximally to the sensor, such as attached directly to the sensor or attached directly to a common substrate with the sensor, i.e., such that the circuit and the sensor are located on the same circuit board.

### Circuit Elements—Amplifier Module:

As described above, circuits of the invention comprise an amplifier module. In embodiments, the amplifier module comprises a first amplifier with differential amplifier outputs. Differential outputs are described above in connection with the circuit. By amplifier, it is meant an electronic circuit with inputs and outputs configured to modify one or more characteristics, such as voltage or current, of an input signal, such as, for example, increase the voltage of an input signal. In embodiments, the first amplifier is an operational amplifier, i.e., an op amp, with differential inputs consisting of inverting and non-inverting inputs as well as differential outputs. Such op amps may be configured to amplify the difference between the non-inverting input signal and inverting input signal. Any commercially available integrated circuit operational amplifier may be employed as the first amplifier, such as op amps available through Texas Instruments or Radio Shack or similar electronic component outlets. In embodiments, the amplifier module comprises a plurality of feedback loops between first amplifier outputs and inputs. That is, a first differential output may be electrically connected to an inverting input of the first amplifier, comprising a feedback loop. Feedback loops around the first amplifier may further comprise a network of circuit elements, such as, for example, a parallel resistor and capacitor, configured to condition an output signal prior to ultimately inputting the signal to either the non-inverting or inverting input of the first amplifier. In some embodiments, the resistances and capacitances in multiple amplifier feedback paths are related, i.e., matched such that corresponding resistors and capacitors have the same resistance and capacitance values. In general, resistors included in feedback loops around the first amplifier have matching tolerances, such as resistor tolerances of 1% or less, such as 0.1% or 0.01% or less.

### Circuit Elements—Baseline Restoration Module:

As described above, baseline restoration circuits of the invention comprise a baseline restoration module. In embodiments, the baseline restoration module comprises a filter network operably connected to the differential amplifier outputs. The differential amplifier outputs comprise the outputs of the first amplifier as described above. The filter network is configured to extract the DC component of the input signal (i.e., the DC component of the signal input from the sensor, as discussed above). In embodiments, the filter network comprises a low-pass filter for extracting a direct current component of the input signal. By “low-pass filter,” it is meant an electronic circuit configured to allow low frequency signals and attenuate high frequency signals. In embodiments, the low-pass filter of the filter network is configured to allow the DC component of the signal and attenuate the data signal component of the input signal (i.e., the component of the signal corresponding to an “event,” as described above, in the context of flow cytometry).

In embodiments, the low pass filter of the filter network comprises a transconductance element and a capacitor. The transconductance element may take two input signals, attached to each of the amplifier differential outputs, and output a single signal, where the amount of current produced at the single transconductance output is based on the difference in voltage at the transconductance inputs. One side of the capacitor may be connected to the transconductance element output and the other side may be grounded. Any commercially available transconductance element and capacitor may be applied, such as transconductance elements or capacitors available through Texas Instruments or Radio Shack or similar electronic component outlets, or such as transconductance elements or capacitors integrated into a substrate such as a printed circuit board. Any convenient capacitance may be applied and may vary. In embodiments, capacitance values may range from 10 μF to 200 μF, such as 10 μF or 50 μF or 75 μF or 150 μF or 200 μF, and may vary depending on, for example, characteristics of the transconductance element as well as the desired low-frequency cut off of the baseline restoration module.

In embodiments, the filter network of the baseline restoration circuit may comprise a feedback loop of the amplifier module. For example, the filter network may comprise a feedback loop of the first amplifier of the amplifier module. In some cases, the inputs of the filter network are connected to the outputs of the amplifier module, for example, the first amplifier, and the outputs of the filter network are ultimately connected to the inputs of the amplifier module, for example, the inputs of the first amplifier. In some cases, the output of the filter network is ultimately connected to an input of the first amplifier. In embodiments, such feedback loop is included in the circuit so that the DC component, having been isolated by the baseline restoration module, fed back into an inverting input of the first amplifier, causes the amplifier to remove or reduce the DC component of the input signal.

In embodiments, baseline restoration modules further comprise a second transconductance element operably connected to the first transconductance element and configured to convert a voltage-based signal to a current-based signal. In such embodiments, the second transconductance element is included to convert a voltage-based signal at the output of the first transconductance element into a current-based signal. Such configuration may be applicable when the input signal to the baseline restoration circuit is a current-based signal such that the current-based input signal is compatible with the current-based output of the baseline restoration module. Any commercially available transconductance element may be applied for the second transconductance element, such as transconductance elements available through Texas Instruments or Radio Shack or similar electronic component outlets, or such as transconductance elements integrated into a substrate such as a printed circuit board.

In embodiments, the baseline restoration network comprises a switch to disengage to the filter network from the circuit. The switch may be a two-position switch allowing the output of the baseline restoration network to be fed back into the amplifier module in a first position and allowing the output of the baseline restoration network to be connected to ground in a second position. In some cases, the switch may be functionally used when long term variations of the signal or dark (leakage) current are observed.

### Input Module:

As described above, baseline restoration circuits of the invention comprise an input module. In embodiments, the input module may be connected to an output from a sensor and the output of the input module may be connected to an input of the amplifier module. In certain embodiments, the input module is configured to transform the input signal received from the sensor. For example, the input module may be configured to transform or convert a current-based input signal received from the sensor to a voltage-based signal. Such a configuration may be applicable in embodiments where the input signal generated by the sensor is a current-based signal, and the amplifier module of the circuit is configured to receive voltage-based signals.

In embodiments, the input module comprises a transistor. The transistor may be any commercially available junction field effect transistor (JFET) available through Texas Instruments or Radio Shack or similar electronic component outlets, or a transistor integrated into a substrate such as a printed circuit board. In embodiments, JFETs of interest may have a unity gain bandwidth of between 1 GHz and 5 GHz, such as a unity gain bandwidth of 3 GHz; in addition, JFETs of interest may have a gate input current of 10 pA or more, such as 10 pA or 20 pA or 30 pA or 50 pA or 100 pA or more. In embodiments, the transistor gate is connected to the input signal from the sensor. The source may be connected to a reference voltage, and the drain may be connected to an input of the amplifier module, such as an inverting input of the first amplifier. Such configuration may be employed to provide a voltage-based signal as output of the input module, based on the current-based signal input from the sensor.

### First Exemplary Embodiment

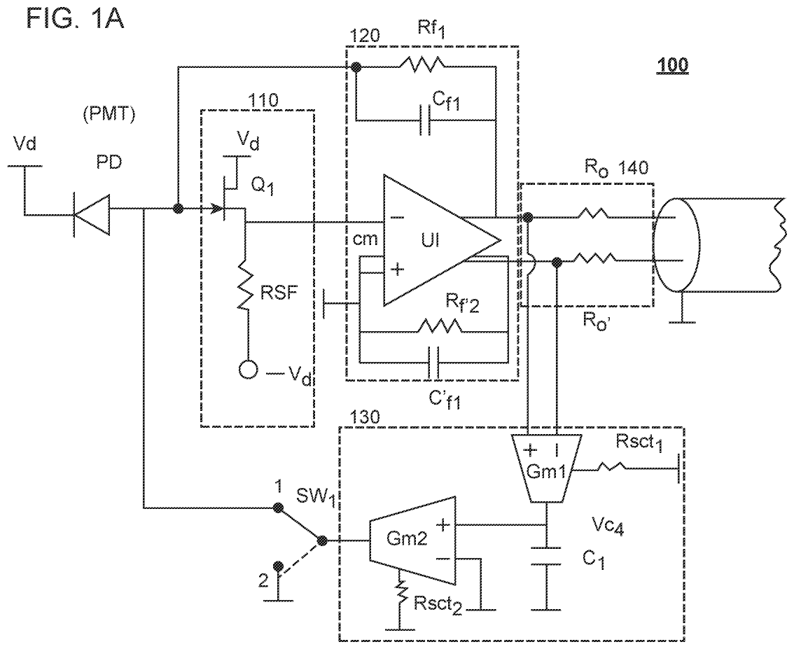

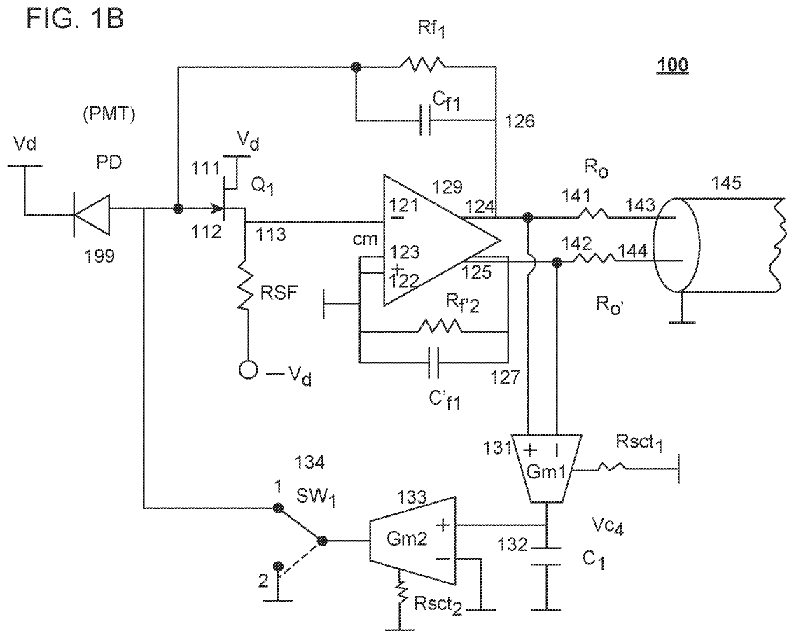

FIG. 1A depicts a baseline restoration circuit with differential outputs according to certain embodiments. Circuit 100 includes input module 110 that is configured to receive an input signal from sensor 199 configured to detect light, for example, light from particles in a flow stream of a flow cytometer. In the embodiment shown, sensor 199 is a photodiode. In this case, circuit 100 is co-located with sensor 199, meaning circuit 100 and sensor 199 are positioned on the same printed circuit board within 1 cm of each other so that a signal generated by sensor 199 would need to travel no more than 1 cm to be input to circuit 100.

Input module 110 is further configured to transform the input signal received from sensor 199 from a current-based signal to a voltage-based signal. The output of input module 110 is operably connected to amplifier module 120 configured to receive a voltage-based input signal and further modify the signal. Amplifier module 120 is operably connected to baseline restoration network 130 configured to extract a direct current component of the input signal and feed such extracted direct current component back to amplifier module 120, via input module 110, thereby enabling amplifier module 120 to subtract or remove or reduce the DC component of the input signal. Output module 140 is operably connected to the output of amplifier module 120 and is configured to transmit a baseline restored signal over differential outputs.

FIG. 1B depicts the baseline restoration circuit with differential outputs 100 of FIG. 1A. Circuit 100 includes input module 110 with JFET transistor 111. Transistor gate 112 is operably connected to output of sensor 199. Amplifier module 120 comprises first amplifier 129. Transistor source 113 is connected to inverting input 121 of first amplifier 129. Transistor source 113 is also connected to reference voltage −V_{d} via resistor RSF. Any convenient resistance value for RSF may be applied and may vary. The resistance may be selected based on the desired and/or acceptable bandwidth and noise of input module 110 and circuit 100. In embodiments, the resistance value for RSF may be selected such that the current represented by (V_{cm}+V_{d})/R_{SF}, where V_{cm} is the common mode potential at cm terminal of amplifier 129 (U₁), is 1 mA or more, such as 3 mA or 4 mA or 5 mA or 10 mA or more. Non-inverting input 122 and common mode input 123 of first amplifier 129 are connected to ground. First amplifier 129 comprises first differential amplifier output 124 and second differential amplifier output 125. First differential amplifier output 124 is fed back to inverting input 121 via resistor and capacitor network 126 and input module 110. Second differential amplifier output 125 is fed back to non-inverting input 122 and common mode input 123 of first amplifier 129 via resistor and capacitor network 127. Any convenient resistance and capacitance values of resistor and capacitor network 126 and resistor and capacitor network 127 may be selected and may vary. In embodiments, the bandwidth of the detected signal is typically less than 1/(2πRC), and resistance and capacitance values, R and C (i.e., R_{f1} and C_{f1} as well as R_{f1}′ and C_{f1}′, in FIGS. 1A and 1B), respectively, of networks 126 and 127 may be selected accordingly. In some embodiments, resistance values, R (i.e., R_{f1} and R_{f1}′), may be 1 KOhms or more, such as 1 KOhms, 10 KOhms, 20 KOhms, 30 KOhms, 40, KOhms, 50 KOhms, 60 KOhms, 70 KOhms, 80 KOhms, 90 KOhms, 100 KOhms or more, and capacitance values, C (i.e., C_{f1} and C_{f1}′), may be 1 pF or more, such as 1 pF, 10 pF, 25 pF, 50 pF, 75 pF, 100 pF, 200 pF, 300 pF, 400 pF, 500 pF. 600 pF, 700 pF, 800 pF, 900 pF or more.

Baseline restoration module 130 comprises first transconductance element 131 and capacitor 132. First differential amplifier output 124 and second differential amplifier output 125 are connected to inputs of first transconductance element 131. Output of transconductance element 131 is connected to capacitor 132. Transconductance element 131 and capacitor 132 are configured to function as a low-pass filter for extracting the DC component of the input signal received from sensor 199. The output of transconductance element 131 is also connected to an input of second transconductance element 133, the other input of which is connected to ground. Second transconductance element 133 is configured to convert the voltage associated with the output of transconductance element 131 to a current-based signal, i.e., to transform a voltage-based signal to a current-based signal. Output of transconductance element 133 is connected to switch 134, which is configured to enable baseline restoration by connecting the output of baseline restoration module 130 to input module 110 or to disable baseline restoration by connecting the output of baseline restoration module 130 to ground. Switch 134 may be functionally used, for example, if long-term variations of the signal or dark (leakage) current are observed.

Output module 140 comprises first resistor 141 and second resistor 142, connected to first differential amplifier output 124 and second differential amplifier output 125, respectively. First resistor 141 and second resistor 142 are configured to absorb reflections at the differential outputs as differential output signals are transmitted along cable core transmission wires 143, 144. Cable core transmission wires 143, 144 may comprise twisted pair and are shielded by common shield 145.

Circuit 100 shown in FIGS. 1A-1B is configured to be an analog front-end used to readout a “bright channel” photodiode (PD). The “bright channel” application is a demanding application for baseline restoration circuits, i.e., DC component cancellation. In typical scenarios in the context of flow cytometry with imaging capability using a wide signal bandwidth, such as, approximately, 80 MHz generates 3 mA of photocurrent as the DC component, while the minimal detectable current should be about 100 nA value (i.e., the current corresponding to a data signal or the input signal of interest, as described above), such as 100 nA±0.1% or more, such as ±0.1% or ±1% or ±5% or more. Changing the circuit parameters allows using the circuit of FIGS. 1A-1B with the photomultipliers (PMTs) of ‘normal’ and photodiodes of the ‘forward scatter’ channels with DC component less than few hundreds of microamperes. In the above two applications, a reduced contribution of the circuit electronic noise is required that may be achieved by configuring the parameters of the circuit in FIGS. 1A-1B as described herein. In addition, when the event rate of the detected signal is high the circuit 100 allows the high-pass filter aspect of the circuit to be configured at very low (below 1 Hz) frequencies, so that pile-up of signal ‘tails’ of preceding events, as described above, have only small contribution to the detected signal magnitude, i.e., the data signal or the input signal of interest.

The photodiode sensor 199 of circuit 100 of FIGS. 1A-1B is reverse biased by voltage V_{d}. That same voltage, V_{d}, also may be used in the source follower biasing in input module 110. The source follower of input module 100 is built around Q1 JFET transistor 111 in circuit 100, such that the drain terminal of transistor 111 is connected to V_{d}. It should be mentioned that a person skilled in the art would recognize that certain filtering of bias potentials like V_{d} and −V_{d} and, in other examples, of some power supply voltages not shown in FIG. 1A-1B, that are present in the readout circuits of flow cytometers may be used for the circuit low noise operation but are not presented in circuit 100 of FIG. 1A-1B. Due to the large signal amplification of photomultiplier tubes (PMTs), the source follower part of input module 110 of circuit 100 may not be necessary and the PMT output may be connected directly to the inverting (i.e., the ‘−’) terminal of U1 differential amplifier 129 in FIGS. 1A-1B.

The input signal generated by the PD sensor 199 that is passed to the source follower of input module 110 is connected to the inverting (i.e., the ‘−’ terminal) of the U1 differential amplifier 129 of circuit 100. The feedback R_{f1}, R_{f1}′ resistors and C_{f1}, C_{f1}′ capacitors in network 126 and network 127 are matched (selection of appropriate resistance and capacitance values for R_{f1} and R_{f1}40 resistors and C_{f1} and C_{f1}′ capacitors is described in detail above), while the common mode, i.e., ‘cm,’ terminal 123 and the non-inverting input terminal ‘+’ 122 of U1 differential amplifier 129 are grounded (or, in some cases, may be connected to some introduced reference potential). The differential outputs 124, 125 of U1 differential amplifier 129 drive the cable core wires 143, 144 through the matched resistors R0, R0′, 141, 142, where wires corresponding to the differential outputs of each channel of a flow cytometer (e.g., each sensor of a flow cytometer) are included in common shield 145 as shown FIG. 1B. As described in detail above, the resistance values of resistors R0 141 and R0′ 142 may be chosen to match the impedance of the cable characteristic impedance (i.e., the impedance of transmission lines 143 144). Any convenient resistances may be applied and may vary depending on, for example, the impedance of the transmission lines used to transmit the differential outputs. In embodiments, resistors may be selected with resistance values of 1 Ohms or more, such as 10 Ohms or 25 Ohms or 50 Ohms or 100 Ohms or more. Resistors may be selected with a tolerance of 1% or less, such as 0.1% or 0.01% or less. Twisted pair in the shield may be used as well for the above purpose. The R0, R0′ resistors 141, 142 values are chosen to absorb the reflections of the load on the remote side of the cable, where the differential signals are received.

The outputs 124, 125 of U1 differential amplifier 129 are connected to the input terminals of the trans-conductor (i.e., transconductance element) Gₘ₁ 131 as shown in FIGS. 1A-1B. The output of Gₘ₁ trans-conductor 131 is loaded at capacitor C₁ 132. The trans-conductance of Gₘ₁ is set by Rₛₑₜ₁ resistor value. The resistance value selected for Rₛₑₜ₁ indicates that trans-conductor Gₘ₁ 131 is tunable (i.e., configurable) and any convenient value may be selected for the resistance value of Rₛₑₜ₁ and accordingly, the configuration of trans-conductor Gₘ₁ 131. In embodiments, the time constant expressed by the ratio of the capacitance of capacitor C₁ 132 over trans-conductor Gₘ₁ 131, i.e., (C₁/Gₘ₁) corresponds to a low frequency cut-off value, as described in connection with the circuit transfer function described in detail below (equation 1 below). In such embodiments, the components, and the corresponding values thereof, are selected so that the expression 1/(2π(C₁/Gₘ₁)) is equal to a frequency that is less than 1 Hz. The capacitor C₁ 131 is charged by the voltage controlled current source of Gₘ₁ 131 controlled by the voltage difference between the output terminals 124, 125 of U1 differential amplifier 129. The voltage on C₁ 132, referred to as V_{c1}, is converted to current in the Gₘ₂ trans-conductor 133 and is connected to one input of transconductor 133. The other input of trans-conductor 133 is connected to ground, but in general may be connected to any constant reference voltage. The control parameter of the trans-conductance Gₘ₂ 133 is set by Rₛₑₜ₂ resistor value. The Rₛₑₜ₂ resistor indicates that trans-conductor Gₘ₂ 133 is tunable (i.e., configurable) and any convenient value may be selected for the resistance value of Rₛₑₜ₂ and accordingly, the configuration of trans-conductor Gₘ₂ 133. The output terminal of Gₘ₂ trans-conductor 133 is connected to the input of the switch SW1 134. In one state, switch 134 allows the Gₘ₂ trans-conductor 133 output connection to the anode of the PD sensor 199, and, in another state, allows a connection to ground potential, as shown in FIGS. 1A-1B. When connected to the PD sensor 199 anode terminal, the base line restoration function is ‘on,’ and otherwise it is ‘off.’ A person skilled in the art will recognize that in practice Gₘ₂ transconductor 133 may be a combination of an amplifier and resistor, or even one appropriately chosen resistor.

Based on a simplified analysis, the following expression describing the transfer function of the input current to the output differential voltage of circuit 100 in the frequency domain may be obtained:

$$H ( j ω ) = \frac{\frac{j ω {C}_{1}}{{G}_{m 1} {G}_{m 2}}}{( 1 + \frac{j ω {C}_{1}}{{G}_{m 1} {G}_{m 2} {R}_{tr}} )} = - \frac{{R}_{tr}}{( 1 + \frac{{G}_{m 1} {G}_{m 2} {R}_{tr}}{j ω {C}_{1}} )} \qquad ( 1 )$$

Rₜᵣ is the trans-impedance of the PD sensor 199 current conversion to the output differential voltage at U1 differential amplifier 129 output terminals 124, 125. That is, Rₜᵣ is the trans-impedance when switch 134 is configured such that base line restoration feedback is ‘off’.

H(jω) is the transfer function for circuit 100 when switch 134 is configured such that base line restoration is turned ‘on’.

It is seen from expression 1 that at high frequencies, the transfer function is determined by Rₜᵣ trans-impedance, while at low frequencies the transfer function zeroes.

### Second Exemplary Embodiment

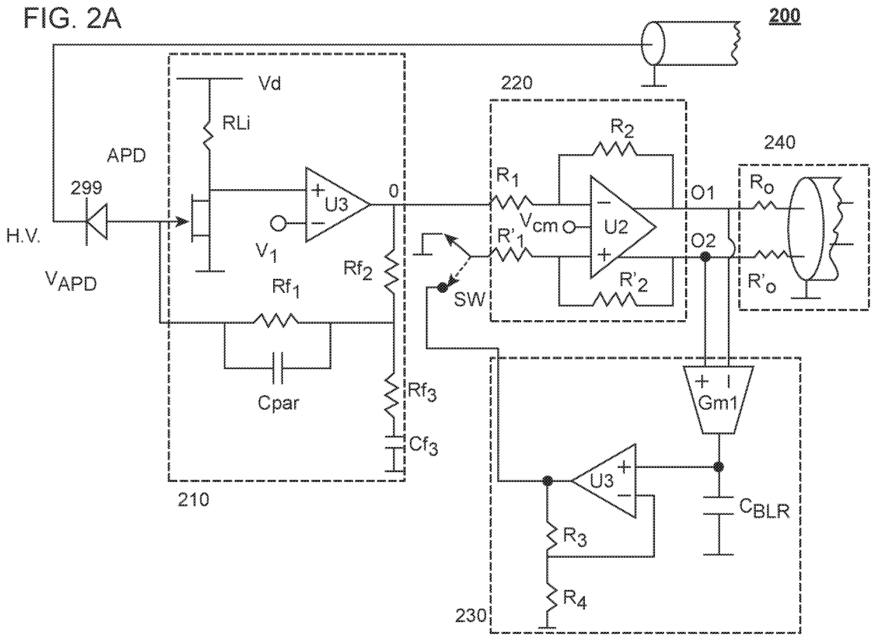

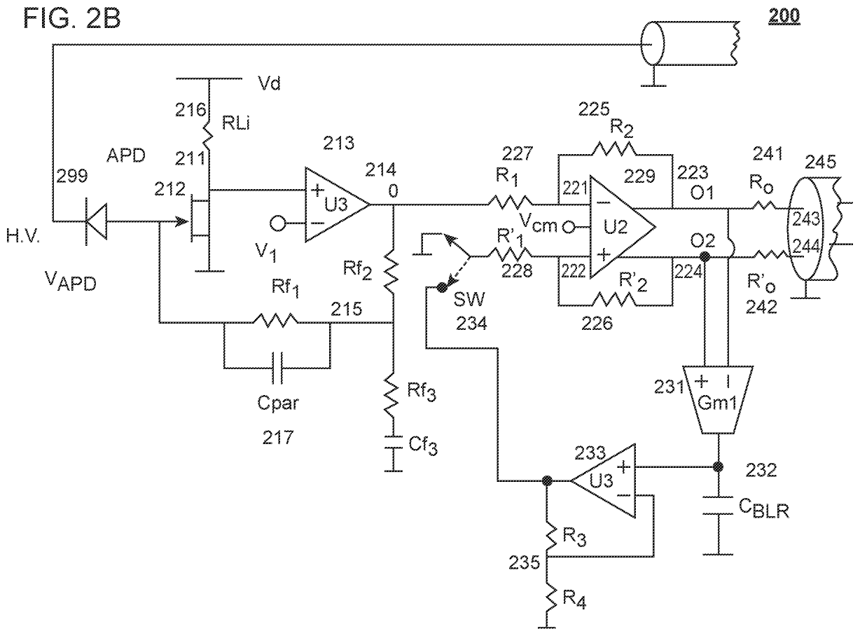

FIG. 2A depicts a baseline restoration circuit with differential outputs according to certain embodiments. Circuit 200 includes input module 210 that is configured to receive an input signal from sensor 299 configured to detect light, for example, light from particles in a flow stream of a flow cytometer. In the embodiment shown, sensor 299 is an avalanche photodiode. In this case, circuit 200 is co-located with sensor 299, meaning circuit 200 and sensor 299 are positioned on the same printed circuit board within 1 cm of each other so that a signal generated by sensor 299 would need to travel no more than 1 cm to be input to circuit 200.

Input module 210 is further configured to transform the input signal received from sensor 299 from a current-based signal to a voltage-based signal. The output of input module 210 is operably connected to amplifier module 220 configured to receive a voltage-based input signal and further transform the signal. Amplifier module 220 is operably connected to baseline restoration network 230 configured to extract a direct current component of the input signal and feed such extracted direct current component back to amplifier module 220, via input module 210, thereby enabling amplifier module 220 to subtract or remove or reduce the DC component of the input signal. Output module 240 is operably connected to the output of amplifier module 220 and is configured to transmit a baseline restored signal over differential outputs.

FIG. 2B depicts the baseline restoration circuit with differential outputs 200 of FIG. 2A. Circuit 200 includes input module 210 with transistor 211. Transistor gate 212 of transistor 211 is operably connected to the output of sensor 299. Input module 210 further comprises amplifier 213. Drain connection of transistor 211 is operably connected to non-inverting input of amplifier U1 213 as well as resistor R_{L1} 216, which is connected to reference voltage V_{d}; source connection of transistor 211 is operably connected to ground. Any convenient resistance value for resistor R_{L1} 216 may be selected and may vary. In embodiments, the resistance value of resistor R_{L1} 216 determines that gain of input module 210 of circuit 200. In such embodiments, resistance values of resistor R_{L1} 216 may be 500 Ohms or greater, such as 750 Ohms or 1 KOhms or 1.5 KOhms or greater. Amplifier U1 213 further transforms the signal input from sensor 299 such that the DC component of the signal can be extracted and then subtracted by subsequent circuit elements. Any convenient amplifier may be selected for amplifier U1 213 and may vary. In embodiments, amplifier U1 213 may be selected such that the unity gain bandwidth of amplifier U1 213 is more than an order of magnitude larger than the bandwidth of the detected signal. Amplifier module 220 comprises first differential amplifier 229. Output 214 of amplifier U1 213 is connected to inverting input 221 of first differential amplifier 229, via resistor R1 227. Output 214 is also connected to the output of sensor 299 via resistor and capacitor network 215, comprising a plurality of resistors, R_{f1}, R_{f2}, R_{f3} and capacitors C_{f3}. Parasitic capacitance is shown with dotted lines as capacitor Cₚₐᵣ 217. In embodiments, any convenient resistance and capacitance values for components of resistor and capacitor network 215 may be selected and may vary. In some cases, resistance and capacitance values may be selected to maximize the bandwidth of circuit 200 by selecting component resistance and capacitance values such that the product of R_{f1} and Cₚₐᵣ (i.e., R_{f1}*Cₚₐᵣ) is approximately equal to the expression ((R_{f2}+R_{f3})*C_{f3}).

Second amplifier 229 comprises first differential amplifier output 223 and second differential amplifier output 224. First differential output 223 of differential amplifier 229 is connected, via resistor R2 225, to inverting input 221 of differential amplifier 229, forming a feedback loop around differential amplifier 229. Second differential output 224 of differential amplifier 229 is connected, via resistor R₂′ 226, to non-inverting input 222 of differential amplifier 229, forming a second feedback loop around differential amplifier 229. Any convenient resistance values for R₂ 225 and R₂′ 226, as well as R₁ 227 and R₁′ 228, may be selected and may vary. In embodiments, resistances of each of these elements may be 1 KOhms or more, such as 1 KOhms, 10 KOhms, 50 KOhms, 100 KOhms, 200 KOhms, 300 KOhms, 400 KOhms, 500 KOhms, 600 KOhms, 700 KOhms, 800 KOhms, 900 KOhms or more. In such embodiments, the resistance values selected for these elements may be determined based on the desired gain of circuit 200, as described in detail below regarding the transfer function of circuit 200 where a gain of circuit 200 corresponds to the value of (K₂R_{f1}), where the element K₂=R₂/R₁=R₂′/R₁′. The common mode input of second differential amplifier 229 is connected to reference voltage V_{cm}. Non-inverting input 222 of second differential amplifier 229 is connected to switch 234 of baseline restoration module 230, via resistor R1′ 228.

Baseline restoration module 230 comprises first transconductance element 231 and capacitor C_{BLR} 232. First differential amplifier output 224 and second differential amplifier output 225 are connected to inputs of first transconductance element 231. Output of transconductance element 231 is connected to capacitor 232. Transconductance element 231 and capacitor 232 are configured to function as a low-pass filter for extracting the DC component of the input signal received from sensor 299. In embodiments, the time constant expressed by the ratio of the capacitance of capacitor C_{BLR} 232 over transconductance element Gₘ 231, i.e., (C_{BLR}/Gₘ) corresponds to a low frequency cut-off value in the circuit transfer function of circuit 200 described in detail below (equation 2 below). In such embodiments, the components, and the corresponding values thereof, are selected so that the expression 1/(2π(C_{BLR}/Gₘ)) equals a frequency that is less than 1 Hz.

The output of transconductance element 231 is also connected to the non-inverting input of amplifier U3 233. The inverting input of amplifier U3 233 is connected to the output of amplifier 233 via voltage divider 235 consisting of two resistors R3 and R4. Any convenient resistance values for elements R3 and R4 may be selected and may vary. In embodiments, resistance values of R3 and R4 may be selected depending on the desired contribution of the expression R3/R4 to the circuit transfer function describing circuit 200 discussed in detail below (equation 2 below).

Amplifier U3 233 is configured to transform the voltage associated with the output of transconductance element 231 into a signal that can ultimately be received by differential amplifier U2 229. Any convenient amplifier may be selected for amplifier U3 233 and may vary. In embodiments, amplifier U3 233 may be selected such that it has a higher bandwidth than the dedicated signal bandwidth. Output of amplifier 233 is connected to switch 234, which is configured to enable baseline restoration by connecting the output of baseline restoration module 230 to amplifier module 220 or to disable baseline restoration by connecting the output of baseline restoration module 230 to ground. Switch 234 may be functionally used, for example, if long-term variations of the signal or dark (leakage) current are observed.

Output module 240 comprises first resistor 241 and second resistor 242, connected to first differential amplifier output 223 and second differential amplifier output 224, respectively. First resistor 241 and second resistor 242 are configured to absorb reflections at the differential outputs as differential output signals are transmitted along cable core transmission wires 243, 244. Cable core transmission wires 243, 244 may comprise twisted pair and are shielded by common shield 245.

As described above, FIG. 2B depicts an exemplary schema for an Avalanche Photodiode (APD) readout where the APD signal current is converted to voltage by the circuit built around amplifier U1 213. The output of amplifier U1 213, i.e., the amplified APD signal, is connected to the gate 212 of JFET transistor 211 for low noise amplification to avoid the APD high gain operation that will result in a high excess noise factor of the APD. The circuit network 215 comprising resistors R_{f2}, R_{f3 and} capacitor C_{f3} circuit elements, enable correction of the bandwidth of the current to voltage conversion when a large value of R_{f1} resistor (i.e., a resistance value in the range of ten MOhms or more such as several hundreds of MOhms or more) is used to lower the equivalent noise current of circuit 200, therefore correcting the bandwidth reduction produced by a parasitic capacitance Cₚₐᵣ 217 of R_{f1} resistor. The signal 214 from the output terminal of amplifier U1 213 is conditioned to the appropriate differential form and gain in the circuit built around differential amplifier U2 229, where R₁ 227, R₁′ 228, and R₂ 225, R₂′ 226 are the matched resistors pairs. The differential outputs 223, 224 of amplifier U2 229 drive the cable core wires 243, 244 through the matched resistors R₀ 241, R₀′ 242, where the core wires corresponding to the differential outputs of each channel are included in the common shield 245 as shown. Resistors R₀ 241, R₀′ 242 values are chosen to absorb the reflections of the load on the remote side of the cable 243, 244, where the differential signal is received.

The output terminals 223, 224 of differential amplifier U2 229 are connected to the inputs of Gₘ trans-conductor 231 that is loaded at C_{BLR} capacitor 232 with the other terminal of the capacitor grounded.

The voltage at the capacitor 232 top terminal is the input to the U3 amplifier 233. The gain of amplifier 233 is set by the resistors R3, R4 values of network 235. The output terminal of amplifier U3 233 may be connected to the input terminal of R₁′ resistor 228 therefore realizing the condition with zero DC voltage across the differential outputs of amplifier U2 229 while the input to the differential amplifier U2 229 is the output signal of amplifier U1 213, which generally has a non-zero DC potential determined by (i) the APD 299 dark current, (ii) the gate voltage of the JFET transistor 211 and (iii) R_{f1} resistor value of network 215. When switch SW1 234 grounds the input terminal of resistor R₁′ 228, the baseline restoration function is “off.”

In a simplified analysis the following expression describing the transfer function of the APD 299 current to the differential output 243, 244 of circuit 200 in the frequency domain may be obtained:

$$H ( j ω ) = \frac{( {V}_{o 1} - {V}_{o 2} )}{{I}_{APD}} = \frac{{R}_{f 1} {K}_{2}}{( 1 + \frac{{G}_{m} {K}_{2}}{j ω {C}_{BLR}} ( \frac{{R}_{3}}{{R}_{4}} + 1 ) )} , \qquad ( 2 )$$

Where K₂ is the transfer function of each branch of differential amplifier U2 229, so that K₂=R₂/R₁=R₂′/R₁′.

It is seen from expression 2 above that the transfer function is determined by the product of R_{f1}K₂ at high frequencies and zeroes at low frequencies.

### Systems for Baseline Restoration Over Differential Outputs

Aspects of the present disclosure include systems for baseline signal restoration over differential outputs. Systems, including flow cytometry systems, for generating, transmitting and receiving baseline restored signals with differential outputs are provided. Certain systems are sensors readout systems. Sensors readout systems according to certain embodiments include a baseline restoration circuit for generating a baseline restored signal on differential outputs as such exemplary circuits are described in detail above, a downstream receiver circuit for receiving a baseline restored signal on differential inputs transmitted by the baseline restoration circuit, and cable core wires configured to connect the differential outputs of the baseline restoration circuit with the differential inputs of the downstream receiver circuit. As described in detail below, the system may comprise part of a flow cytometry system and may be used to elucidate a meaningful signal in the context of a significant and varying DC component of the sensor output.

Embodiments of a sensor readout system according to the present invention may include any convenient baseline restoration circuit, such as baseline restoration circuits coupled to differential outputs described above, where an analog baseline restored signal is generated and transmitted over differential outputs. In embodiments, the downstream receiver circuit is configured to convert differential signals received from the baseline restoration circuit into digital signals. That is, the downstream receiver circuit is configured to transform the baseline restored signal transmitted on differential outputs into a digital signal. Conversion into a digital signal may be desirable to facilitate further processing and/or analysis of the baseline restored signal as desired.

### Downstream Receiver Circuit:

Embodiments of downstream receiver circuits according to the present invention include an anti-alias filter module operably connected to the differential inputs, a kickback protection module operably connected to the output of the anti-alias filter module, and an analog-to-digital converter module operably connected to the output of the kickback protection module for converting signals received from the baseline restoration circuit into digital signals. As noted above, the differential inputs of downstream receiver circuits are operably connected to differential outputs of the baseline restoration circuit.

Any convenient anti-alias filter circuit, such as in some cases, a low-pass filter, for use in restricting the bandwidth of the sampled signal to a bandwidth of interest so as to the sampled signal reflects the true signal and not an aliased signal may be applied. That is, the anti-alias filter may be configured as needed to satisfy the Nyquist-Shannon sampling theorem over the band of interest. In embodiments, the anti-alias filter module comprises an amplifier with differential inputs and differential outputs. The module may be configured to include one or more feedback loops or paths among the differential outputs and differential inputs. In embodiments, the anti-alias filter amplifier comprises a network of resistors and capacitors. In other embodiments, the anti-alias filter module is configured to receive two differential offset control voltages as additional inputs. In such embodiments, the anti-alias filter module may be configured such that the differential offset control voltages shift the input signal (i.e., the signal received from the baseline restoration circuit originating from a sensor) in order to utilize the full range of the downstream analog to digital converter.

In embodiments, the output of the anti-alias filter module may be operably connected to a kickback protection module. Any circuit configured to prevent voltage or current spikes, including reverse polarity voltage or current spikes, may be applied for the kick-back protection circuit in embodiments. For example, anti-alias filter modules of embodiments may comprise capacitors configured to absorb any such spikes. In some embodiments, the kickback protection module comprises a network of resistors and capacitors.

In embodiments, the output of the kickback protection module is operably connected to an analog-to-digital converter module. The analog-to-digital converter is configured to convert a baseline restored signal in analog, differential form, to a digital signal. Any convenient analog-to-digital converter may be used, including any commercially available, off the shelf analog-to-digital converter, and may vary in embodiments depending on the desired range or granularity of digital signal required for subsequent signal processing.

In embodiments, the analog to digital converter module of the downstream receiver circuit comprises differential inputs. That is, the analog to digital converter is configured to convert an analog signal represented as the difference between the signal on each of the differential inputs, where the signal may be a voltage signal, current signal, combinations thereof, or other signal characteristic. The output of the analog to digital converter depends on the resolution of the analog to digital converter selected in embodiments and may vary. In embodiments, the analog to digital converter outputs may comprise four or more bits of digital signal, such as eight bits, or 16 bits, or 32 bits or 64 bits or more.

### High Voltage Signal for Sensor Gain:

In some embodiments, the downstream receiver circuit further comprises a voltage source module configured to generate a high voltage control potential signal for a sensor. That is, the high voltage control potential signal for a sensor may be utilized to bias the sensor in connection with generating data signals based on events detected by the sensor. In embodiments, the high voltage control potential signal comprises a sensor gain setting for a light detector. Such light detector may be an avalanche photodiode sensor or a photodiode sensor or a photomultiplier tube sensor, for example. In embodiments, the voltage source module comprises a DC-to-DC converter, where any commercially available, off the shelf DC-to-DC converter may be applied, such as those available from electronic components warehouses or Texas Instruments or Radio Shack or the like. That is, the DC-to-DC converter may be configured to step up a lower input voltage to a higher output DC voltage. Such converter may be configured to receive a control signal for controlling the degree to which the voltage of the input DC signal is stepped up. In some embodiments, the voltage source module comprises a feedback network configured to compare the high voltage control potential signal with a reference voltage. That is, the module may be configured to compare the output signal of the DC-to-DC converter to a reference voltage and, based on such comparison, adjust a control signal controlling the DC-to-DC converter.

### Digital to Analog Converter:

In embodiments, the voltage source module comprises a digital-to-analog converter operably connected to the output of the DC-to-DC converter and configured to output the high voltage control potential signal for transmission to a sensor and offset control voltages for the anti-alias filter. That is, the digital to analog converter may be used to control the gain in a sensor, such as, for example, a light sensor comprising an avalanche photo diode. In addition, the digital to analog converter may also control the differential offsets described above for use in the anti-alias module for shifting the input signal to an appropriate range for subsequent conversion to a digital signal. In embodiments, outputs of the digital to analog converter are voltages; the digital to analog converter may be configured via codes that control the output voltages, which codes are set via a programmable interface to the digital to analog converter.

### High Voltage Signal on Cable Core Transmission Wires:

In embodiments of sensors readout systems, the cable core wires further comprise a high voltage transmission line operably connected to and configured to control the high voltage control potential signal to a sensor. In some embodiments, the sensor is co-located with the baseline restoration circuit. By “co-located,” it is meant that the sensor is proximal to the baseline restoration circuit, such as being located on the same substrate or printed circuit board. In some cases, the sensor is located within 10 cm or less of the baseline restoration circuit, such as within 1 cm or less of the baseline restoration circuit or within 0.1 cm or less of the baseline restoration circuit. Such embodiments, enable baseline restoration of the signal generated by the sensor to occur prior to transmitting a baseline restored signal over differential outputs to a downstream receiver circuit. Such a configuration, where baseline restoration occurs immediately upon receiving input signals, may offer improved signal processing at the downstream receiver circuit or at circuits further downstream thereof.

### Exemplary Embodiment of Downstream Receiver Circuit:

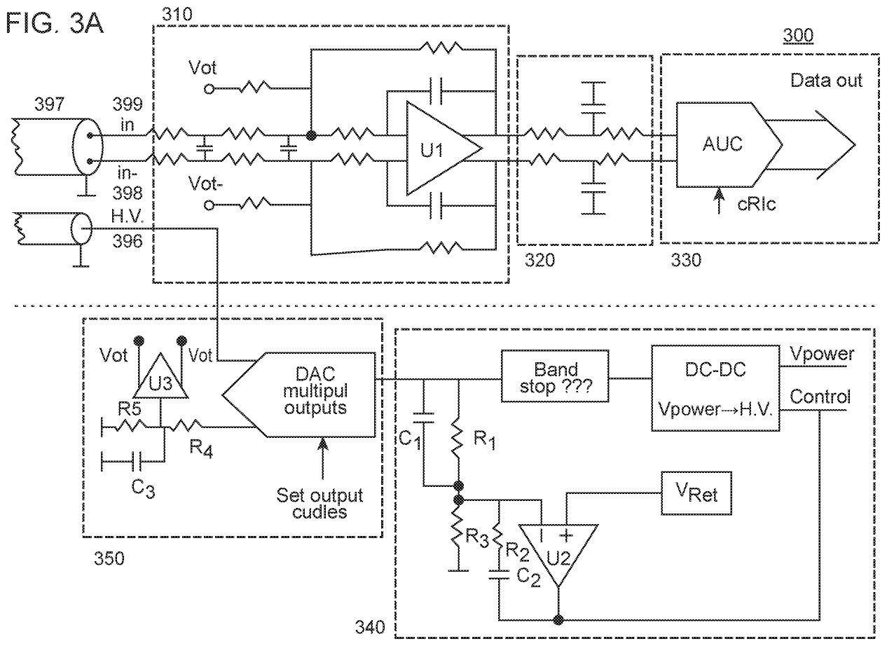

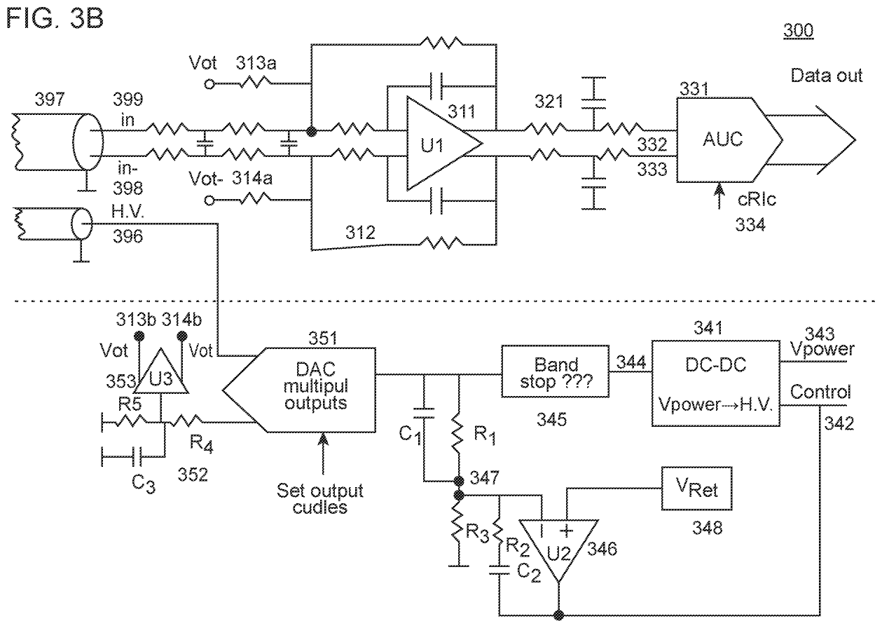

FIG. 3A depicts a downstream receiver circuit with differential inputs according to certain embodiments. Circuit 300 includes anti-alias filter module 310 that is configured to receive differential inputs, in and in_, 398, 399 over cable core wires. As described above, such differential inputs 398, 399 are used to transmit baseline restored signals in differential form to the downstream receiver circuit. In the embodiment shown, along with differential inputs 398, 399 is common shield 397. Anti-alias filter module 310 is further configured to receive offset signals, V_{of} and V_{of-} as inputs.

The output of anti-alias filter module 310 is operably connected to kickback protection module 320 configured to absorb any voltage or current spikes, including reverse polarity voltage spikes. The output of kickback protection module 320 is operably connected to analog-to-digital converter module 330 configured to convert the analog differential signal input to the downstream receiver circuit, such differential ultimately arising from a sensor attached to a baseline restoration circuit, to a digital signal that may be referred to as dataout.

Also seen in FIG. 3A, is an output consisting of high voltage control potential signal for a sensor 396. Such high voltage signal 396 is generated by voltage source module 340, operably connected to high voltage control potential signal for a sensor 396. High voltage control potential signal for a sensor 396 is operably connected to a sensor (not shown) via shielded cable core wires, where the sensor is proximal to a baseline restoration circuit but not necessarily proximal to downstream receiver circuit 300. Voltage source module 340 is operably connected to digital-to-analog converter module 350, which is configured to transmit high voltage control potential signal for a sensor 396.

FIG. 3B depicts the downstream receiver circuit with differential inputs 300 of FIG. 3A. Circuit 300 includes anti-alias filter module 310 with amplifier U1 311 with differential inputs and differential outputs that form feedback paths between amplifier U1 311 inputs and outputs through resistor and capacitor network 312. Any convenient resistance and capacitance values for the components of resistor and capacitor network 312 may be selected and may vary. In embodiments, resistance and capacitance values may be selected such that they improve the effectiveness of anti-alias filter module 310 while simultaneously generating low or minimal noise in the signals transmitted through anti-alias filter module 310. Anti-alias filter module 310 is configured to receive two differential control voltages V_{of} and V_{of}− 313a, 314a, where the anti-alias filter module is configured to shift input signals 398,399 so as to utilize the full range of downstream analog to digital converter 331.

FIG. 3B depicts how kickback protection module comprises network of resistors and capacitors 321, including capacitors connected to ground, configured to absorb or otherwise mitigate the effect of reverse polarity voltage or current spikes. Network of resistors and capacitors 321 are symmetrical with respect to each of the two differential inputs 398, 399. Outputs of kickback protection module 320 are operably connected to differential inputs 332, 333 of analog-to-digital converter 331. Analog to digital converter 331 is configured to convert the analog signal conveyed by the difference in signals on input 332 and input 333 into a digital signal, dataout.

Voltage source module 340 comprises DC-to-DC converter 341 configured to receive input DC power 343 which is stepped up to high voltage output DC power 344 as controlled by control input 342. High voltage output DC power 344 is operably connected to band stop filter 345 to further modify the high voltage signal prior to transmitting it to a sensor along high voltage transmission line 396. Voltage source module comprises a circuit configured to control the high voltage signal built around amplifier 346 configured to act as a continuous time regulator between output 344 of DC-to-DC converter 341 and a reference voltage and to adjust the input control 342 to the DC-to-DC converter based on the result of such continuous time regulator circuit built around amplifier 346.

Voltage source module 340 is operably connected to digital to analog converter 351, which is programmed to generate high voltage signal 396 transmitted over cable core wires to sensor. In addition, digital to analog converter is configured to generate differential control voltages V_{of} and V_{of}− 313b, 314b, which are electrically connected to differential control voltages V_{of} and V_{of}− 313a, 314a, above in the figure.

As described above, FIGS. 3A-3B depict an exemplary embodiment of the downstream receiver circuit, where such circuit may be present on a circuit board, on the receiver (acquisition) side for a photodetector front-end readout, such as baseline restoration circuits described above. The differential signal generated in the photodetectors readout front-ends, as described above, for example, in connection with FIGS. 1A-1B and 2A-2B, is received at terminals ‘in’ and ‘in_’ 398, 399, one pair for each readout channel. Only one readout channel is shown in FIGS. 3A-3B. The downstream receiver circuit embodiment shown in FIGS. 3A-3B starts with the third order anti alias-filter 310 built around amplifier U1 311. The outputs of the filter 310 drive the inputs 332, 333 of the analog to digit converter (ADC) 331 through kick back protection circuitry 320 shown in between the outputs of amplifier U1 311 and the ADC inputs 332, 333 in FIGS. 3A-3B. The rate of the clock signal ‘clk’ 334, input to ADC 331, allows for varying the oversampling ratio while the signal bandwidth is determined by anti-alias filter 310. Photodetector gain control and biasing voltages 396 are generated in the circuit 300 shown on the same board in FIGS. 3A-3B. Designated as ‘H.V.’ 396 these voltages are introduced into the cable system, one for each readout channel. Any convenient resistance and capacitance values may be selected for the resistor and capacitor components shown in FIGS. 3A-3B. In embodiments, resistance and capacitance values may be selected to support the stability of the high voltage (H.V.) regulator functionality of circuit 300.

Linear mode APDs that are frequently used as photodetectors, for example, in the context of flow cytometry, require approximately 200 V or less biasing for their operation. The approximately 200 V voltage is generated from a low voltage power ‘V_{power}’ 343 using DC-DC′ converter 341. To maintain the gain stability the generated high voltage is compared using the continuous time regulator circuit built around amplifier 346 with the stable on board voltage reference ‘V_{ref}’ 348 using the resistive divider R₁, R₃ 347 and operational amplifier U2 346. The output of amplifier U2 346 is applied to the control terminal ‘control’ 342 of DC-DC converter 341. Any residual ripple of DC-DC conversion is suppressed using band stop filter 345 for the conversion frequency range and the appropriate R₁C₁ and R₂C₂ time constants of the circuitry that support the stability when band stop filter 345 is included into the feedback control loop of DC-DC′ converter 341. The circuit embodiment shown in FIGS. 3A-3B allows few mV of ripple at the DC-DC conversion frequency and few ppm/C temperature stability of the ‘DC-DC’ output voltage of approximately 200 V.

Output of band stop filter 345 is operably connected to the input of high voltage digital to analog converter ‘DAC’ 351 that has multiple programmable outputs, the ‘DAC’ output impedances are low, such, as for example, 100 Ohms or less, such as 50 Ohms. One part of the of ‘DAC’ 351 outputs is used for the APDs gain control 396 in multiple channels (only one channel is shown in FIGS. 3A-3B). The outputs are operably connected, i.e., wired, to the cable terminals designated as ‘H.V.’ The other part of the ‘DAC’ 351 output voltages is converted into the differential offset control voltages V_{of}, V_{of_} 313b, 314b that are applied to anti-alias filter 310 at 313a, 314a of each readout channel as shown in FIGS. 3A-3B (only one channel readout is shown in FIGS. 3A-3B). Extra voltage division with R₄, R₅ resistors and a filtering capacitor C₃ 352 to implement above function are shown in FIGS. 3A-3B circuit 300, where the divided signal is converted into the differential form in amplifier U3 353. As the polarity of the detected photocurrent never changes the voltage that is applied to ‘ADC’ 331 inputs in differential form should allow the ADC conversion using the full scale—i.e., full range of the ADC—when working with the unipolar photocurrent. This is achieved by shifting the signal at the ADC inputs 332, 333 to the lowest of the highest input voltage using programmable V_{of}, V_{of_} offset voltages 313, 314. The choice for the lowest or the highest voltage depends on how many inversions the signal undergoes before being presented to ‘ADC’ 331. In the embodiment shown in FIGS. 3A-3B, the voltage shift towards the highest voltage is used in the APD readout to save the number of components that circuit 300 requires.

Flow Cytometry Systems with Baseline Restoration Over Differential Outputs:

As described above, aspects of the present disclosure include flow cytometry systems for generating, transmitting and receiving baseline restored signals with differential outputs. Flow cytometry systems according to the present invention include a light source configured to irradiate a sample comprising particles flowing in a flow stream, a light detection system comprising a light sensor for detecting light from the particles in the sample and generating a data signal based on the detected light, and a sensors readout system, such as the sensors readout systems described above.

In some embodiments, the baseline restoration circuit is located remotely from the downstream receiver circuit. In other embodiments, the downstream receiver circuit generates a high voltage control potential signal for the light sensor. In such embodiments, the high voltage control potential signal may comprise a gain setting for the light sensor. In some cases, the high voltage control potential signal is transmitted to the light detection system via the cable core wires, wherein the cable core wires are operably connected to the downstream receiver circuit and the light detection system. In certain cases, the system further comprises processing the data signal detected by the light sensor remotely from the light detection system. By “remotely,” it is meant not proximal such as at a distance of 1 cm or greater, such as 10 cm or 100 cm or more. In some cases, remotely processing means the sensor and the baseline restoration circuit of the system are remote from the downstream receiver circuit, such as at a distance of 1 cm or greater, such as 10 cm or 100 cm or more. In embodiments, processing the data signal detected by the light sensor comprises converting the data signal into a digital signal.

In embodiments, the systems include a light source for irradiating a particle propagating through a flow stream. In some embodiments, the light source continuously irradiates the particle propagating through the flow stream across an interrogation region of the flow stream of 5 μm or more, such as 10 μm or more, such as 15 μm or more, such as 20 μm or more, such as 25 μm or more, such as 50 μm or more, such as 75 μm or more, such as 100 μm or more, such as 250 μm or more, such as 500 μm or more, such as 750 μm or more, such as for example across an interrogation region of 1 mm or more, such as 2 mm or more, such as 3 mm or more, such as 4 mm or more, such as 5 mm or more, such as 6 mm or more, such as 7 mm or more, such as 8 mm or more, such as 9 mm or more and including 10 mm or more.

In some embodiments, the light source is configured to irradiate a planar cross-section of the propagated flow stream or may be configured to facilitate irradiation of a diffuse field (e.g., with a diffuse laser or lamp) of a predetermined length. In some embodiments, the region of the flow stream interrogated by the light source in the subject systems includes a transparent window that facilitates irradiation of a predetermined length of an emanating flow stream, such as 0.0001 mm or more, such as 0.0005 mm or more, such as 0.001 mm or more, such as 0.005 mm or more, such as 0.01 mm or more, such as 0.05 mm or more, such as 0.1 mm or more, such as 0.5 mm or more, such as 1 mm or more and including 5 mm or more. Depending on the light source used to irradiate the flow stream (as described below), the transparent window which facilitates irradiation of the flow stream by the light source may be configured to pass light that ranges from 100 nm to 1500 nm, such as from 150 nm to 1400 nm, such as from 200 nm to 1300 nm, such as from 250 nm to 1200 nm, such as from 300 nm to 1100 nm, such as from 350 nm to 1000 nm, such as from 400 nm to 900 nm and including from 500 nm to 800 nm.

In embodiments, the systems include a light source for irradiating the particle propagating through in the flow stream. In some embodiments, the light source is a continuous wave light source, such as where the light source provides uninterrupted light flux and maintains irradiation of particles in the flow stream with little to no undesired changes in light intensity. In some embodiments, the continuous light source emits non-pulsed or non-stroboscopic irradiation. In certain embodiments, the continuous light source provides for substantially constant emitted light intensity. For instance, the continuous light source may provide for emitted light intensity during a time interval of irradiation that varies by 10% or less, such as by 9% or less, such as by 8% or less, such as by 7% or less, such as by 6% or less, such as by 5% or less, such as by 4% or less, such as by 3% or less, such as by 2% or less, such as by 1% or less, such as by 0.5% or less, such as by 0.1% or less, such as by 0.01% or less, such as by 0.001% or less, such as by 0.0001% or less, such as by 0.00001% or less and including where the emitted light intensity during a time interval of irradiation varies by 0.000001% or less. The intensity of light output can be measured with any convenient protocol, including but not limited to, a scanning slit profiler, a charge coupled device (CCD, such as an intensified charge coupled device, ICCD), a positioning sensor, power sensor (e.g., a thermopile power sensor), optical power sensor, energy meter, digital laser photometer, a laser diode detector, among other types of photodetectors.

In some embodiments, the light source includes one or more pulsed light sources, such as where light is emitted at predetermined time intervals, each time interval having a predetermined irradiation duration (i.e., pulse width). In certain embodiments, the pulsed light source is configured to continuously irradiate the particle propagating through the flow stream with periodic flashes of light. For example, the frequency of each light pulse may be 0.0001 kHz or greater, such as 0.0005 kHz or greater, such as 0.001 kHz or greater, such as 0.005 kHz or greater, such as 0.01 kHz or greater, such as 0.05 kHz or greater, such as 0.1 kHz or greater, such as 0.5 kHz or greater, such as 1 kHz or greater, such as 2.5 kHz or greater, such as 5 kHz or greater, such as 10 kHz or greater, such as 25 kHz or greater, such as 50 kHz or greater and including 100 kHz or greater. In certain instances, the frequency of pulsed irradiation by the light source ranges from 0.00001 kHz to 1000 kHz, such as from 0.00005 kHz to 900 kHz, such as from 0.0001 kHz to 800 kHz, such as from 0.0005 kHz to 700 kHz, such as from 0.001 kHz to 600 kHz, such as from 0.005 kHz to 500 kHz, such as from 0.01 kHz to 400 kHz, such as from 0.05 kHz to 300 kHz, such as from 0.1 kHz to 200 kHz and including from 1 kHz to 100 kHz. The duration of light irradiation for each light pulse (i.e., pulse width) may vary and may be 0.000001 ms or more, such as 0.000005 ms or more, such as 0.00001 ms or more, such as 0.00005 ms or more, such as 0.0001 ms or more, such as 0.0005 ms or more, such as 0.001 ms or more, such as 0.005 ms or more, such as 0.01 ms or more, such as 0.05 ms or more, such as 0.1 ms or more, such as 0.5 ms or more, such as 1 ms or more, such as 2 ms or more, such as 3 ms or more, such as 4 ms or more, such as 5 ms or more, such as 10 ms or more, such as 25 ms or more, such as 50 ms or more, such as 100 ms or more and including 500 ms or more. For example, the duration of light irradiation may range from 0.000001 ms to 1000 ms, such as from 0.000005 ms to 950 ms, such as from 0.00001 ms to 900 ms, such as from 0.00005 ms to 850 ms, such as from 0.0001 ms to 800 ms, such as from 0.0005 ms to 750 ms, such as from 0.001 ms to 700 ms, such as from 0.005 ms to 650 ms, such as from 0.01 ms to 600 ms, such as from 0.05 ms to 550 ms, such as from 0.1 ms to 500 ms, such as from 0.5 ms to 450 ms, such as from 1 ms to 400 ms, such as from 5 ms to 350 ms and including from 10 ms to 300 ms.

Systems may include any convenient light source and may include laser and non-laser light sources. In certain embodiments, the light source is a non-laser light source, such as a narrow band light source emitting a particular wavelength or a narrow range of wavelengths. In some instances, the narrow band light sources emit light having a narrow range of wavelengths, such as for example, 50 nm or less, such as 40 nm or less, such as 30 nm or less, such as 25 nm or less, such as 20 nm or less, such as 15 nm or less, such as 10 nm or less, such as 5 nm or less, such as 2 nm or less and including light sources which emit a specific wavelength of light (i.e., monochromatic light). Any convenient narrow band light source protocol may be employed, such as a narrow wavelength LED.

In other embodiments, the light source is a broadband light source, such as a broadband light source coupled to one or more optical bandpass filters, diffraction gratings, monochromators or any combination thereof. In some instances, the broadband light source emits light having a broad range of wavelengths, such as for example, spanning 50 nm or more, such as 100 nm or more, such as 150 nm or more, such as 200 nm or more, such as 250 nm or more, such as 300 nm or more, such as 350 nm or more, such as 400 nm or more and including spanning 500 nm or more. For example, one suitable broadband light source emits light having wavelengths from 200 nm to 1500 nm. Another example of a suitable broadband light source includes a light source that emits light having wavelengths from 400 nm to 1000 nm. Any convenient broadband light source protocol may be employed, such as a halogen lamp, deuterium arc lamp, xenon arc lamp, stabilized fiber-coupled broadband light source, a broadband LED with continuous spectrum, superluminescent emitting diode, semiconductor light emitting diode, wide spectrum LED white light source, an multi-LED integrated white light source, among other broadband light sources or any combination thereof. In certain embodiments, light sources include an array of LEDs. In certain instances, the light source includes a plurality of monochromatic light emitting diodes where each monochromatic light emitting diode outputs light having a different wavelength. In some instances, the light source includes a plurality of polychromatic light emitting diodes outputting light having a predetermined spectral width, such as where the plurality of polychromatic light emitting diodes collectively output light having a spectral width that ranges from 200 nm to 1500 nm, such as from 225 nm to 1475 nm, such as from 250 nm to 1450 nm, such as from 275 nm to 1425 nm, such as from 300 nm to 1400 nm, such as from 325 nm to 1375 nm, such as from 350 nm to 1350 nm, such as from 375 nm to 1325 nm, such as from 400 nm to 1300 nm, such as from 425 nm to 1275 nm, such as from 450 nm to 1250 nm, such as from 475 nm to 1225 nm and including from 500 nm to 1200 nm.

In certain embodiments, the light source includes a laser, such as a pulsed or continuous wave laser. For example, the laser may be a diode laser, such as an ultraviolet diode laser, a visible diode laser and a near-infrared diode laser. In other embodiments, the laser may be a helium-neon (HeNe) laser. In some instances, the laser is a gas laser, such as a helium-neon laser, argon laser, krypton laser, xenon laser, nitrogen laser, CO₂ laser, CO laser, argon-fluorine (ArF) excimer laser, krypton-fluorine (KrF) excimer laser, xenon chlorine (XeCl) excimer laser or xenon-fluorine (XeF) excimer laser or a combination thereof. In other instances, the subject systems include a dye laser, such as a stilbene, coumarin or rhodamine laser. In yet other instances, lasers of interest include a metal-vapor laser, such as a helium-cadmium (HeCd) laser, helium-mercury (HeHg) laser, helium-selenium (HeSe) laser, helium-silver (HeAg) laser, strontium laser, neon-copper (NeCu) laser, copper laser or gold laser and combinations thereof. In still other instances, the subject systems include a solid-state laser, such as a ruby laser, an Nd:YAG laser, NdCrYAG laser, Er:YAG laser, Nd:YLF laser, Nd:YVO₄ laser, Nd:YCa₄O(BO₃)₃ laser, Nd:YCOB laser, titanium sapphire laser, thulim YAG laser, ytterbium YAG laser, ytterbium₂O₃ laser or cerium doped lasers and combinations thereof.

In some embodiments, the light source is a narrow bandwidth light source. In some instance, the light source is a light source that outputs a specific wavelength from 200 nm to 1500 nm, such as from 250 nm to 1250 nm, such as from 300 nm to 1000 nm, such as from 350 nm to 900 nm and including from 400 nm to 800 nm. In certain embodiments, the continuous wave light source emits light having a wavelength of 365 nm, 385 nm, 405 nm, 460 nm, 490 nm, 525 nm, 550 nm, 580 nm, 635 nm, 660 nm, 740 nm, 770 nm or 850 nm.

In some embodiments, the light source emits light having wavelengths that overlap, such as where the output spectrum of one or more components of the lights source overlap by 1 nm or more, such as by 2 nm or more, such as by 3 nm or more, such as by 4 nm or more, such as by 5 nm or more, such as by 6 nm or more, such as by 7 nm or more, such as by 8 nm or more, such as by 9 nm or more, such as by 10 nm or more and including by 20 nm or more. In some embodiments, the wavelengths of light emitted by the light sources exhibit no overlap. For example, the output spectrum of the light sources may be separated by 1 nm or more, such as by 2 nm or more, such as by 3 nm or more, such as by 4 nm or more, such as by 5 nm or more, such as by 6 nm or more, such as by 7 nm or more, such as by 8 nm or more, such as by 9 nm or more, such as by 10 nm or more and including by 20 nm or more.

The light source may be positioned by any suitable distance from the flow stream, such as at a distance of 0.001 mm or more, such as 0.005 mm or more, such as 0.01 mm or more, such as 0.05 mm or more, such as 0.1 mm or more, such as 0.5 mm or more, such as 1 mm or more, such as 5 mm or more, such as 10 mm or more, such as 25 mm or more and including at a distance of 100 mm or more. In addition, the light source may be positioned at any suitable angle relative to the flow stream such as at an angle ranging from 10° to 90°, such as from 15° to 85°, such as from 20° to 80°, such as from 25° to 75° and including from 30° to 60°, for example at a 90° angle.

Light sources according to certain embodiments may also include one or more optical adjustment components. The term “optical adjustment” is used herein in its conventional sense to refer to any device that is capable of changing the spatial width of irradiation or some other characteristic of irradiation from the light source, such as for example, irradiation direction, wavelength, beam width, beam intensity and focal spot. Optical adjustment protocols may be any convenient device which adjusts one or more characteristics of the light source, including but not limited to lenses, mirrors, filters, fiber optics, wavelength separators, pinholes, slits, collimating protocols and combinations thereof. In certain embodiments, systems of interest include one or more focusing lenses. The focusing lens, in one example may be a de-magnifying lens. In another example, the focusing lens is a magnifying lens. In other embodiments, systems of interest include one or more mirrors. In still other embodiments, systems of interest include fiber optics.

As described above, systems are configured to irradiate a particle propagating through a flow stream and light from the irradiated particle is continuously conveyed through a light adjustment component to a detector as the particle is propagated through the flow stream. In some instances, light from the irradiated particle is emitted light such as fluorescence from the particle. In some instances, light from the irradiated particle is scattered light. In some cases, the scattered light is forward scattered light. In some cases, the scattered light is backscattered light. In some cases, the scattered light is side scattered light. In some instances, light from the irradiated particle is transmitted light.

Photodetectors of the subject systems may be any convenient light detecting protocol, including but not limited to photosensors or photodetectors, such as active-pixel sensors (APSs), quadrant photodiodes, image sensors, charge-coupled devices (CCDs), intensified charge-coupled devices (ICCDs), light emitting diodes, photon counters, bolometers, pyroelectric detectors, photoresistors, photovoltaic cells, photodiodes, photomultiplier tubes, phototransistors, quantum dot photoconductors or photodiodes and combinations thereof, among other photodetectors. In certain embodiments, the photodetector is a photomultiplier tube, such as a photomultiplier tube having an active detecting surface area of each region that ranges from 0.01 cm² to 10 cm², such as from 0.05 cm² to 9 cm², such as from, such as from 0.1 cm² to 8 cm², such as from 0.5 cm² to 7 cm² and including from 1 cm² to 5 cm².

In embodiments of the present disclosure, the photodetector may be configured to detect light at one or more wavelengths, such as at 2 or more wavelengths, such as at 5 or more different wavelengths, such as at 10 or more different wavelengths, such as at 25 or more different wavelengths, such as at 50 or more different wavelengths, such as at 100 or more different wavelengths, such as at 200 or more different wavelengths, such as at 300 or more different wavelengths and including measuring light at 400 or more different wavelengths.

Photodetectors of embodiments of the invention may be configured to measure light continuously or in discrete intervals. In some instances, detectors of interest are configured to take measurements of the light continuously. In other instances, detectors of interest are configured to take measurements in discrete intervals, such as measuring light every 0.001 millisecond, every 0.01 millisecond, every 0.1 millisecond, every 1 millisecond, every 10 milliseconds, every 100 milliseconds and including every 1000 milliseconds, or some other interval.

The photodetectors may be configured to take measurements of the light one or more times during each discrete time interval, such as 2 or more times, such as 3 or more times, such as 5 or more times and including 10 or more times. In certain embodiments, light is measured by the photodetector 2 or more times, with the data in certain instances being averaged.

In certain embodiments, systems further include a flow cell configured to propagate the particle in the flow stream. Any convenient flow cell which propagates a fluidic sample to a sample interrogation region may be employed, where in some embodiments, the flow cell includes a proximal cylindrical portion defining a longitudinal axis and a distal frustoconical portion which terminates in a flat surface having the orifice that is transverse to the longitudinal axis. The length of the proximal cylindrical portion (as measured along the longitudinal axis) may vary ranging from 1 mm to 15 mm, such as from 1.5 mm to 12.5 mm, such as from 2 mm to 10 mm, such as from 3 mm to 9 mm and including from 4 mm to 8 mm. The length of the distal frustoconical portion (as measured along the longitudinal axis) may also vary, ranging from 1 mm to 10 mm, such as from 2 mm to 9 mm, such as from 3 mm to 8 mm and including from 4 mm to 7 mm. The diameter of the of the flow cell nozzle chamber may vary, in some embodiments, ranging from 1 mm to 10 mm, such as from 2 mm to 9 mm, such as from 3 mm to 8 mm and including from 4 mm to 7 mm.

In certain instances, the flow cell does not include a cylindrical portion and the entire flow cell inner chamber is frustoconically shaped. In these embodiments, the length of the frustoconical inner chamber (as measured along the longitudinal axis transverse to the nozzle orifice), may range from 1 mm to 15 mm, such as from 1.5 mm to 12.5 mm, such as from 2 mm to 10 mm, such as from 3 mm to 9 mm and including from 4 mm to 8 mm. The diameter of the proximal portion of the frustoconical inner chamber may range from 1 mm to 10 mm, such as from 2 mm to 9 mm, such as from 3 mm to 8 mm and including from 4 mm to 7 mm.

In some embodiments, the sample flow stream emanates from an orifice at the distal end of the flow cell. Depending on the desired characteristics of the flow stream, the flow cell orifice may be any suitable shape where cross-sectional shapes of interest include, but are not limited to, rectilinear cross sectional shapes, e.g., squares, rectangles, trapezoids, triangles, hexagons, etc., curvilinear cross-sectional shapes, e.g., circles, ovals, as well as irregular shapes, e.g., a parabolic bottom portion coupled to a planar top portion. In certain embodiments, flow cell of interest has a circular orifice. The size of the nozzle orifice may vary, in some embodiments ranging from 1 μm to 20000 μm, such as from 2 μm to 17500 μm, such as from 5 μm to 15000 μm, such as from 10 μm to 12500 μm, such as from 15 μm to 10000 μm, such as from 25 μm to 7500 μm, such as from 50 μm to 5000 μm, such as from 75 μm to 1000 μm, such as from 100 μm to 750 μm and including from 150 μm to 500 μm. In certain embodiments, the nozzle orifice is 100 μm.

In some embodiments, the flow cell includes a sample injection port configured to provide a sample to the flow cell. In embodiments, the sample injection system is configured to provide suitable flow of sample to the flow cell inner chamber. Depending on the desired characteristics of the flow stream, the rate of sample conveyed to the flow cell chamber by the sample injection port may be 1 μL/min or more, such as 2 μL/min or more, such as 3 μL/min or more, such as 5 μL/min or more, such as 10 μL/min or more, such as 15 μL/min or more, such as 25 μL/min or more, such as 50 μL/min or more and including 100 μL/min or more, where in some instances the rate of sample conveyed to the flow cell chamber by the sample injection port is 1 μL/sec or more, such as 2 μL/sec or more, such as 3 μL/sec or more, such as 5 μL/sec or more, such as 10 μL/sec or more, such as 15 μL/sec or more, such as 25 μL/sec or more, such as 50 μL/sec or more and including 100 μL/sec or more.

The sample injection port may be an orifice positioned in a wall of the inner chamber or may be a conduit positioned at the proximal end of the inner chamber. Where the sample injection port is an orifice positioned in a wall of the inner chamber, the sample injection port orifice may be any suitable shape where cross-sectional shapes of interest include, but are not limited to, rectilinear cross sectional shapes, e.g., squares, rectangles, trapezoids, triangles, hexagons, etc., curvilinear cross-sectional shapes, e.g., circles, ovals, etc., as well as irregular shapes, e.g., a parabolic bottom portion coupled to a planar top portion. In certain embodiments, the sample injection port has a circular orifice. The size of the sample injection port orifice may vary depending on shape, in certain instances, having an opening ranging from 0.1 mm to 5.0 mm, e.g., 0.2 to 3.0 mm, e.g., 0.5 mm to 2.5 mm, such as from 0.75 mm to 2.25 mm, such as from 1 mm to 2 mm and including from 1.25 mm to 1.75 mm, for example 1.5 mm.

In certain instances, the sample injection port is a conduit positioned at a proximal end of the flow cell inner chamber. For example, the sample injection port may be a conduit positioned to have the orifice of the sample injection port in line with the flow cell orifice. Where the sample injection port is a conduit positioned in line with the flow cell orifice, the cross-sectional shape of the sample injection tube may be any suitable shape where cross-sectional shapes of interest include, but are not limited to: rectilinear cross sectional shapes, e.g., squares, rectangles, trapezoids, triangles, hexagons, etc., curvilinear cross-sectional shapes, e.g., circles, ovals, as well as irregular shapes, e.g., a parabolic bottom portion coupled to a planar top portion. The orifice of the conduit may vary depending on shape, in certain instances, having an opening ranging from 0.1 mm to 5.0 mm, e.g., 0.2 to 3.0 mm, e.g., 0.5 mm to 2.5 mm, such as from 0.75 mm to 2.25 mm, such as from 1 mm to 2 mm and including from 1.25 mm to 1.75 mm, for example 1.5 mm. The shape of the tip of the sample injection port may be the same or different from the cross-section shape of the sample injection tube. For example, the orifice of the sample injection port may include a beveled tip having a bevel angle ranging from 1° to 10°, such as from 2° to 9°, such as from 3° to 8°, such as from 4° to 7° and including a bevel angle of 5°.

In some embodiments, the flow cell also includes a sheath fluid injection port configured to provide a sheath fluid to the flow cell. In embodiments, the sheath fluid injection system is configured to provide a flow of sheath fluid to the flow cell inner chamber, for example in conjunction with the sample to produce a laminated flow stream of sheath fluid surrounding the sample flow stream. Depending on the desired characteristics of the flow stream, the rate of sheath fluid conveyed to the flow cell chamber by the may be 25 μL/sec or more, such as 50 μL/sec or more, such as 75 μL/sec or more, such as 100 μL/sec or more, such as 250 μL/sec or more, such as 500 μL/sec or more, such as 750 μL/sec or more, such as 1000 μL/sec or more and including 2500 μL/sec or more.

In some embodiments, the sheath fluid injection port is an orifice positioned in a wall of the inner chamber. The sheath fluid injection port orifice may be any suitable shape where cross-sectional shapes of interest include, but are not limited to, rectilinear cross sectional shapes, e.g., squares, rectangles, trapezoids, triangles, hexagons, etc., curvilinear cross-sectional shapes, e.g., circles, ovals, as well as irregular shapes, e.g., a parabolic bottom portion coupled to a planar top portion. The size of the sample injection port orifice may vary depending on shape, in certain instances, having an opening ranging from 0.1 mm to 5.0 mm, e.g., 0.2 to 3.0 mm, e.g., 0.5 mm to 2.5 mm, such as from 0.75 mm to 2.25 mm, such as from 1 mm to 2 mm and including from 1.25 mm to 1.75 mm, for example 1.5 mm.

In some embodiments, systems further include a pump in fluid communication with the flow cell to propagate the flow stream through the flow cell. Any convenient fluid pump protocol may be employed to control the flow of the flow stream through the flow cell. In certain instances, systems include a peristaltic pump, such as a peristaltic pump having a pulse damper. The pump in the subject systems is configured to convey fluid through the flow cell at a rate suitable for detecting light from the sample in the flow stream. In some instances, the rate of sample flow in the flow cell is 1 μL/min (microliter per minute) or more, such as 2 μL/min or more, such as 3 μL/min or more, such as 5 μL/min or more, such as 10 μL/min or more, such as 25 μL/min or more, such as 50 μL/min or more, such as 75 μL/min or more, such as 100 μL/min or more, such as 250 μL/min or more, such as 500 μL/min or more, such as 750 μL/min or more and including 1000 μL/min or more. For example, the system may include a pump that is configured to flow sample through the flow cell at a rate that ranges from 1 μL/min to 500 μL/min, such as from 1 uL/min to 250 uL/min, such as from 1 uL/min to 100 uL/min, such as from 2 μL/min to 90 μL/min, such as from 3 μL/min to 80 μL/min, such as from 4 μL/min to 70 μL/min, such as from 5 μL/min to 60 μL/min and including from 10 μL/min to 50 μL/min. In certain embodiments, the flow rate of the flow stream is from 5 μL/min to 6 μL/min.

In certain embodiments, the subject systems are flow cytometric systems. Suitable flow cytometry systems may include, but are not limited to, those described in Ormerod (ed.), Flow Cytometry: A Practical Approach, Oxford Univ. Press (1997); Jaroszeski et al. (eds.), Flow Cytometry Protocols, Methods in Molecular Biology No. 91, Humana Press (1997); Practical Flow Cytometry, 3rd ed., Wiley-Liss (1995); Virgo, et al. (2012) Ann Clin Biochem. January; 49(pt 1):17-28; Linden, et. al., Semin Throm Hemost. 2004 October; 30(5):502-11; Alison, et al. J Pathol, 2010 December; 222(4):335-344; and Herbig, et al. (2007) Crit Rev Ther Drug Carrier Syst. 24(3):203-255; the disclosures of which are incorporated herein by reference. In certain instances, flow cytometry systems of interest include BD Biosciences FACSCanto™ flow cytometer, BD Biosciences FACSCanto™ II flow cytometer, BD Accuri™ flow cytometer, BD Accuri™ C6 Plus flow cytometer, BD Biosciences FACSCelesta™ flow cytometer, BD Biosciences FACSLyric™ flow cytometer, BD Biosciences FACSVerse™ flow cytometer, BD Biosciences FACSymphony™ flow cytometer, BD Biosciences LSRFortessa™ flow cytometer, BD Biosciences LSRFortessa™ X-20 flow cytometer, BD Biosciences FACSPresto™ flow cytometer, BD Biosciences FACSVia™ flow cytometer and BD Biosciences FACSCalibur™ cell sorter, a BD Biosciences FACSCount™ cell sorter, BD Biosciences FACSLyric™ cell sorter, BD Biosciences Via™ cell sorter, BD Biosciences Influx™ cell sorter, BD Biosciences Jazz™ cell sorter, BD Biosciences Aria™ cell sorter, BD Biosciences FACSAria™ II cell sorter, BD Biosciences FACSAria™ III cell sorter, BD Biosciences FACSAria™ Fusion cell sorter and BD Biosciences FACSMelody™ cell sorter, BD Biosciences FACSymphony™ S6 cell sorter or the like.

In some embodiments, the subject systems are flow cytometric systems, such those described in U.S. Pat. Nos. 10,663,476; 10,620,111; 10,613,017; 10,605,713; 10,585,031; 10,578,542; 10,578,469; 10,481,074; 10,302,545; 10,145,793; 10,113,967; 10,006,852; 9,952,076; 9,933,341; 9,726,527; 9,453,789; 9,200,334; 9,097,640; 9,095,494; 9,092,034; 8,975,595; 8,753,573; 8,233,146; 8,140,300; 7,544,326; 7,201,875; 7,129,505; 6,821,740; 6,813,017; 6,809,804; 6,372,506; 5,700,692; 5,643,796; 5,627,040; 5,620,842; 5,602,039; 4,987,086; 4,498,766; the disclosures of which are herein incorporated by reference in their entirety.

In certain instances, flow cytometry systems of the invention are configured for imaging particles in a flow stream by fluorescence imaging using radiofrequency tagged emission (FIRE), such as those described in Diebold, et al. Nature Photonics Vol. 7(10); 806-810 (2013) as well as described in U.S. Pat. Nos. 9,423,353; 9,784,661; 9,983,132; 10,006,852; 10,078,045; 10,036,699; 10,222,316; 10,288,546; 10,324,019; 10,408,758; 10,451,538; 10,620,111; and U.S. Patent Publication Nos. 2017/0133857; 2017/0328826; 2017/0350803; 2018/0275042; 2019/0376895 and 2019/0376894 the disclosures of which are herein incorporated by reference.

In some embodiments, methods include sorting components of a sample, such as described in U.S. Pat. Nos. 10,006,852; 9,952,076; 9,933,341; 9,784,661; 9,726,527; 9,453,789; 9,200,334; 9,097,640; 9,095,494; 9,092,034; 8,975,595; 8,753,573; 8,233,146; 8,140,300; 7,544,326; 7,201,875; 7,129,505; 6,821,740; 6,813,017; 6,809,804; 6,372,506; 5,700,692; 5,643,796; 5,627,040; 5,620,842; 5,602,039; the disclosures of which are herein incorporated by reference in their entirety. In some embodiments, methods for sorting components of sample include sorting particles (e.g., cells in a biological sample) with an enclosed particle sorting module, such as those described in U.S. Patent Publication No. 2017/0299493, the disclosure of which is incorporated herein by reference. In certain embodiments, particles (e.g., cells) of the sample are sorted using a sort decision module having a plurality of sort decision units, such as those described in U.S. Patent Publication No. 2020/0256781, the disclosure of which is incorporated herein by reference. In some embodiments, methods for sorting components of sample include sorting particles (e.g., cells in a biological sample) with a particle sorting module having deflector plates, such as described in U.S. Patent Publication No. 2017/0299493, filed on Mar. 28, 2017, the disclosure of which is incorporated herein by reference.

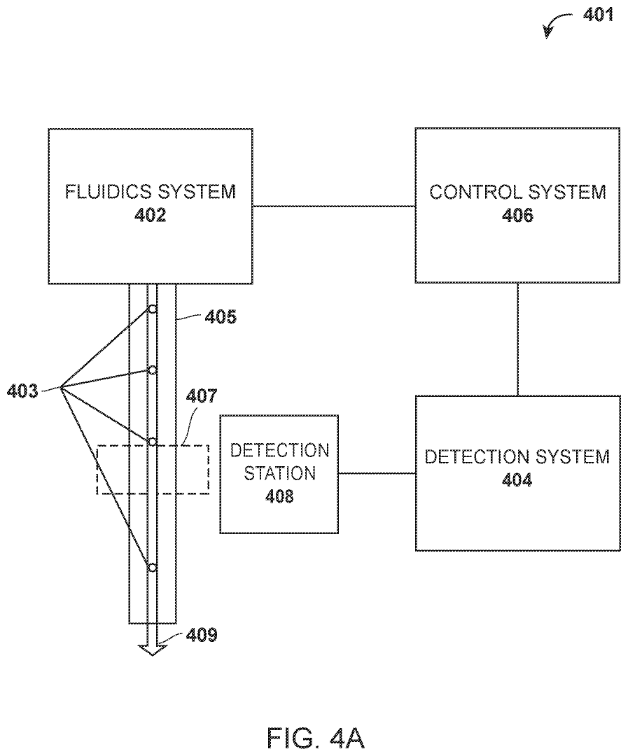

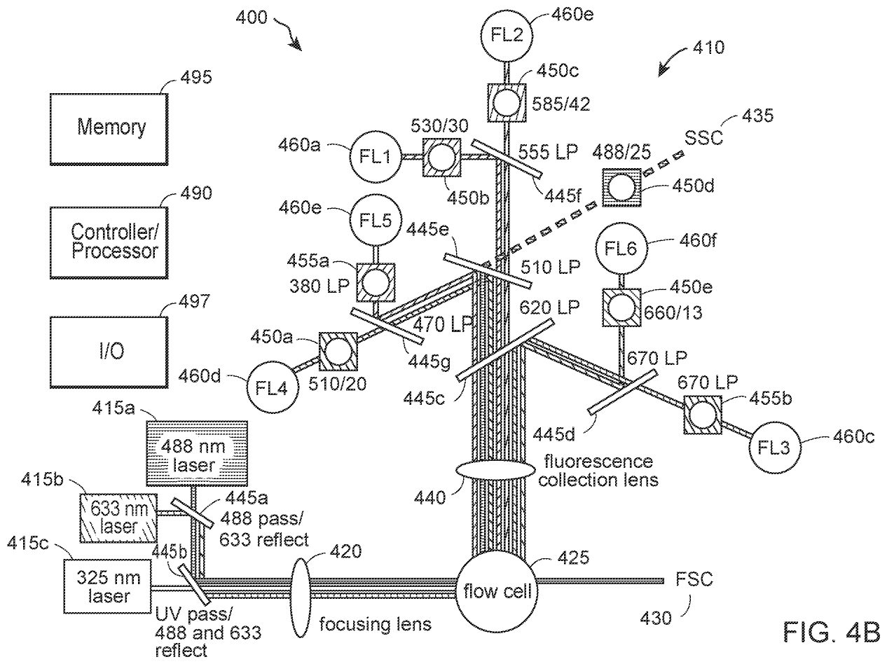

In some embodiments, systems are particle analyzers where the particle analysis system 401 (FIG. 4A) can be used to analyze and characterize particles, with or without physically sorting the particles into collection vessels. FIG. 4A shows a functional block diagram of a particle analysis system for computational based sample analysis and particle characterization. In some embodiments, the particle analysis system 401 is a flow system. The particle analysis system 401 shown in FIG. 4A can be configured to perform, in whole or in part, the methods described herein, such as baseline restoration of signals acquired by detection system 404. The particle analysis system 401 includes a fluidics system 402. The fluidics system 402 can include or be coupled with a sample tube 405 and a moving fluid column within the sample tube in which particles 403 (e.g. cells) of a sample move along a common sample path 409.

The particle analysis system 401 includes a detection system 404 configured to collect a signal from each particle as it passes one or more detection stations along the common sample path. A detection station 408 generally refers to a monitored area 407 of the common sample path. Detection can, in some implementations, include detecting light or one or more other properties of the particles 403 as they pass through a monitored area 407. In FIG. 4A, one detection station 408 with one monitored area 407 is shown. Some implementations of the particle analysis system 401 can include multiple detection stations. Furthermore, some detection stations can monitor more than one area. Detection stations can include an embodiment of baseline restoration circuits described herein.

Each signal is assigned a signal value to form a data point for each particle. As described above, this data can be referred to as event data. The data point can be a multidimensional data point including values for respective properties measured for a particle. The detection system 404 is configured to collect a succession of such data points in a first time interval.

The particle analysis system 401 can also include a control system 406. The control system 406 can include one or more processors, an amplitude control circuit and/or a frequency control circuit. The control system shown can be operationally associated with the fluidics system 402. The control system can be configured to generate a calculated signal frequency for at least a portion of the first time interval based on a Poisson distribution and the number of data points collected by the detection system 404 during the first time interval. The control system 406 can be further configured to generate an experimental signal frequency based on the number of data points in the portion of the first time interval. The control system 406 can additionally compare the experimental signal frequency with that of a calculated signal frequency or a predetermined signal frequency.

In some embodiments, an example of a flow cytometry system is shown in FIG. 4B. System 400 includes a flow cytometer 410, a controller/processor 490 and a memory 495. The flow cytometer 410 includes one or more excitation lasers 415a-415c, a focusing lens 420, a flow chamber 425, a forward scatter detector 430, a side scatter detector 435, a fluorescence collection lens 440, one or more beam splitters 445a-445g, one or more bandpass filters 450a-450e, one or more longpass (“LP”) filters 455a-455b, and one or more fluorescent detectors 460a-460f.

The excitation lasers 115a-c emit light in the form of a laser beam. The wavelengths of the laser beams emitted from excitation lasers 415a-415c are 488 nm, 633 nm, and 325 nm, respectively, in the example system of FIG. 4B. The laser beams are first directed through one or more of beam splitters 445a and 445b. Beam splitter 445a transmits light at 488 nm and reflects light at 633 nm. Beam splitter 445b transmits UV light (light with a wavelength in the range of 10 to 400 nm) and reflects light at 488 nm and 633 nm.

The laser beams are then directed to a focusing lens 420, which focuses the beams onto the portion of a fluid stream where particles of a sample are located, within the flow chamber 425. The flow chamber is part of a fluidics system which directs particles, typically one at a time, in a stream to the focused laser beam for interrogation. The flow chamber can comprise a flow cell in a benchtop cytometer or a nozzle tip in a stream-in-air cytometer.

The light from the laser beam(s) interacts with the particles in the sample by diffraction, refraction, reflection, scattering, and absorption with re-emission at various different wavelengths depending on the characteristics of the particle such as its size, internal structure, and the presence of one or more fluorescent molecules attached to or naturally present on or in the particle. The fluorescence emissions as well as the diffracted light, refracted light, reflected light, and scattered light may be routed to one or more of the forward scatter detector 430, the side scatter detector 435, and the one or more fluorescent detectors 460a-460f through one or more of the beam splitters 445a-445g, the bandpass filters 450a-450e, the longpass filters 455a-455b, and the fluorescence collection lens 440.

The fluorescence collection lens 440 collects light emitted from the particle-laser beam interaction and routes that light towards one or more beam splitters and filters. Bandpass filters, such as bandpass filters 450a-450e, allow a narrow range of wavelengths to pass through the filter. For example, bandpass filter 450a is a 510/20 filter. The first number represents the center of a spectral band. The second number provides a range of the spectral band. Thus, a 510/20 filter extends 10 nm on each side of the center of the spectral band, or from 500 nm to 520 nm. Shortpass filters transmit wavelengths of light equal to or shorter than a specified wavelength. Longpass filters, such as longpass filters 455a-455b, transmit wavelengths of light equal to or longer than a specified wavelength of light. For example, longpass filter 455a, which is a 670 nm longpass filter, transmits light equal to or longer than 670 nm. Filters are often selected to optimize the specificity of a detector for a particular fluorescent dye. The filters can be configured so that the spectral band of light transmitted to the detector is close to the emission peak of a fluorescent dye.

Beam splitters direct light of different wavelengths in different directions. Beam splitters can be characterized by filter properties such as shortpass and longpass. For example, beam splitter 445g is a 620 SP beam splitter, meaning that the beam splitter 445g transmits wavelengths of light that are 620 nm or shorter and reflects wavelengths of light that are longer than 620 nm in a different direction. In one embodiment, the beam splitters 445a-445g can comprise optical mirrors, such as dichroic mirrors.

The forward scatter detector 430 is positioned slightly off axis from the direct beam through the flow cell and is configured to detect diffracted light, the excitation light that travels through or around the particle in mostly a forward direction. The intensity of the light detected by the forward scatter detector is dependent on the overall size of the particle. The forward scatter detector can include a photodiode. The side scatter detector 435 is configured to detect refracted and reflected light from the surfaces and internal structures of the particle and tends to increase with increasing particle complexity of structure. The fluorescence emissions from fluorescent molecules associated with the particle can be detected by the one or more fluorescent detectors 460a-460f. The side scatter detector 435 and fluorescent detectors can include photomultiplier tubes. The signals detected at the forward scatter detector 430, the side scatter detector 435 and the fluorescent detectors can be converted to electronic signals (voltages) by the detectors. This data can provide information about the sample. Detectors may comprise or may be integrated with baseline restoration circuits as described herein.

One of skill in the art will recognize that a flow cytometer in accordance with an embodiment of the present invention is not limited to the flow cytometer depicted in FIG. 4B, but can include any flow cytometer known in the art. For example, a flow cytometer may have any number of lasers, beam splitters, filters, and detectors at various wavelengths and in various different configurations.

In operation, cytometer operation is controlled by a controller/processor 490, and the measurement data from the detectors can be stored in the memory 495 and processed by the controller/processor 490. Although not shown explicitly, the controller/processor 490 is coupled to the detectors to receive the output signals therefrom and may also be coupled to electrical and electromechanical components of the flow cytometer 400 to control the lasers, fluid flow parameters, and the like. For example, in embodiments, the controller/processor 490 may comprise or may be coupled to downstream receiver circuits with differential outputs for receiving baseline restored signals over differential outputs from detectors. Input/output (I/O) capabilities 497 may be provided also in the system, including cable core wires as described herein. The memory 495, controller/processor 490, and I/O 497 may be entirely provided as an integral part of the flow cytometer 410. In such an embodiment, a display may also form part of the I/O capabilities 497 for presenting experimental data to users of the cytometer 400. Alternatively, some or all of the memory 495 and controller/processor 490 and I/O capabilities may be part of one or more external devices such as a general purpose computer. In some embodiments, some or all of the memory 495 and controller/processor 490 can be in wireless or wired communication with the cytometer 410. The controller/processor 490 in conjunction with the memory 495 and the I/O 497 can be configured to perform various functions related to the preparation and analysis of a flow cytometer experiment.

The system illustrated in FIG. 4B includes six different detectors that detect fluorescent light in six different wavelength bands (which may be referred to herein as a “filter window” for a given detector) as defined by the configuration of filters and/or splitters in the beam path from the flow cell 425 to each detector. In embodiments, baseline restoration circuits may be associated with and co-located with each detector. Different fluorescent molecules used for a flow cytometer experiment will emit light in their own characteristic wavelength bands. The particular fluorescent labels used for an experiment and their associated fluorescent emission bands may be selected to generally coincide with the filter windows of the detectors. However, as more detectors are provided, and more labels are utilized, perfect correspondence between filter windows and fluorescent emission spectra is not possible. It is generally true that although the peak of the emission spectra of a particular fluorescent molecule may lie within the filter window of one particular detector, some of the emission spectra of that label will also overlap the filter windows of one or more other detectors. This may be referred to as spillover. The I/O 497 can be configured to receive data regarding a flow cytometer experiment having a panel of fluorescent labels and a plurality of cell populations having a plurality of markers, each cell population having a subset of the plurality of markers. The I/O 497 can also be configured to receive biological data assigning one or more markers to one or more cell populations, marker density data, emission spectrum data, data assigning labels to one or more markers, and cytometer configuration data. Flow cytometer experiment data, such as label spectral characteristics and flow cytometer configuration data can also be stored in the memory 495. The controller/processor 490 can be configured to evaluate one or more assignments of labels to markers.

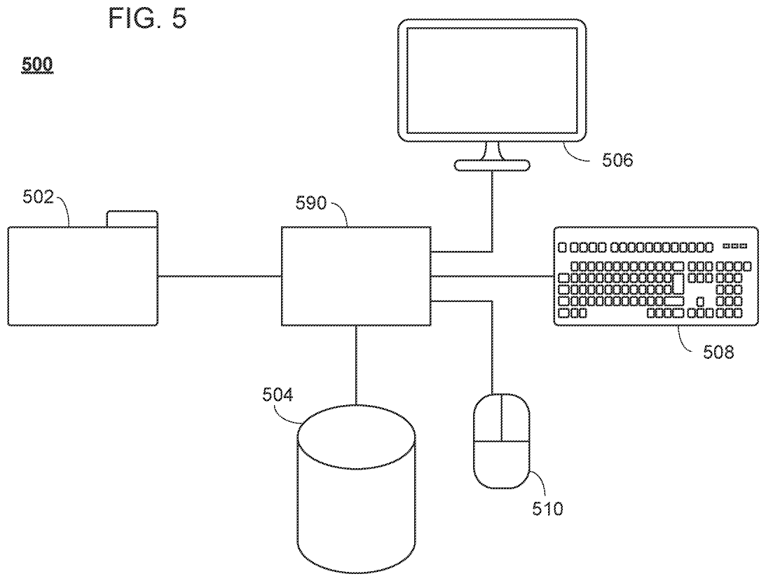

FIG. 5 shows a functional block diagram for one example of a particle analyzer control system, such as an analytics controller 500, for analyzing and displaying biological events. An analytics controller 500 can be configured to implement a variety of processes for controlling graphic display of biological events.

A particle analyzer or sorting system 502 can be configured to acquire biological event data. For example, a flow cytometer can generate flow cytometric event data. The particle analyzer 502 can be configured to provide biological event data to the analytics controller 500. A data communication channel can be included between the particle analyzer or sorting system 502 and the analytics controller 500. The biological event data can be provided to the analytics controller 500 via the data communication channel. Such biological event data may consist of baseline restored signals, or data based on baseline restored signals, originating from sensors with baseline restoration circuits of the present invention installed in particle analyzer or sorting system 502.

The analytics controller 500 can be configured to receive biological event data from the particle analyzer or sorting system 502. The biological event data received from the particle analyzer or sorting system 502 can include flow cytometric event data. As described above, such flow cytometric event data may consist of or be based on signals processed with a baseline restoration circuit, prior to transmitting to analytics controller 500. The analytics controller 500 can be configured to provide a graphical display including a first plot of biological event data to a display device 506. The analytics controller 500 can be further configured to render a region of interest as a gate around a population of biological event data shown by the display device 506, overlaid upon the first plot, for example. In some embodiments, the gate can be a logical combination of one or more graphical regions of interest drawn upon a single parameter histogram or bivariate plot. In some embodiments, the display can be used to display particle parameters or saturated detector data.

The analytics controller 500 can be further configured to display the biological event data on the display device 506 within the gate differently from other events in the biological event data outside of the gate. For example, the analytics controller 500 can be configured to render the color of biological event data contained within the gate to be distinct from the color of biological event data outside of the gate. The display device 506 can be implemented as a monitor, a tablet computer, a smartphone, or other electronic device configured to present graphical interfaces.

The analytics controller 500 can be configured to receive a gate selection signal identifying the gate from a first input device. For example, the first input device can be implemented as a mouse 510. The mouse 510 can initiate a gate selection signal to the analytics controller 500 identifying the gate to be displayed on or manipulated via the display device 506 (e.g., by clicking on or in the desired gate when the cursor is positioned there). In some implementations, the first device can be implemented as the keyboard 508 or other means for providing an input signal to the analytics controller 500 such as a touchscreen, a stylus, an optical detector, or a voice recognition system. Some input devices can include multiple inputting functions. In such implementations, the inputting functions can each be considered an input device. For example, as shown in FIG. 5, the mouse 510 can include a right mouse button and a left mouse button, each of which can generate a triggering event.

The triggering event can cause the analytics controller 500 to alter the manner in which the data is displayed, which portions of the data is actually displayed on the display device 506, and/or provide input to further processing such as selection of a population of interest for particle sorting. In some embodiments, the analytics controller 500 can be configured to detect when gate selection is initiated by the mouse 510. The analytics controller 500 can be further configured to automatically modify plot visualization to facilitate the gating process. The modification can be based on the specific distribution of biological event data received by the analytics controller 500. The analytics controller 500 can be connected to a storage device 504.

The storage device 504 can be configured to receive and store biological event data from the analytics controller 500. The storage device 504 can also be configured to receive and store flow cytometric event data from the analytics controller 500. The storage device 504 can be further configured to allow retrieval of biological event data, such as flow cytometric event data, by the analytics controller 500.

A display device 506 can be configured to receive display data from the analytics controller 500. The display data can comprise plots of biological event data and gates outlining sections of the plots. The display device 506 can be further configured to alter the information presented according to input received from the analytics controller 500 in conjunction with input from the particle analyzer 502, the storage device 504, the keyboard 508, and/or the mouse 510.

In some implementations, the analytics controller 500 can generate a user interface to receive example events for sorting. For example, the user interface can include a control for receiving example events or example images. The example events or images or an example gate can be provided prior to collection of event data for a sample or based on an initial set of events for a portion of the sample.

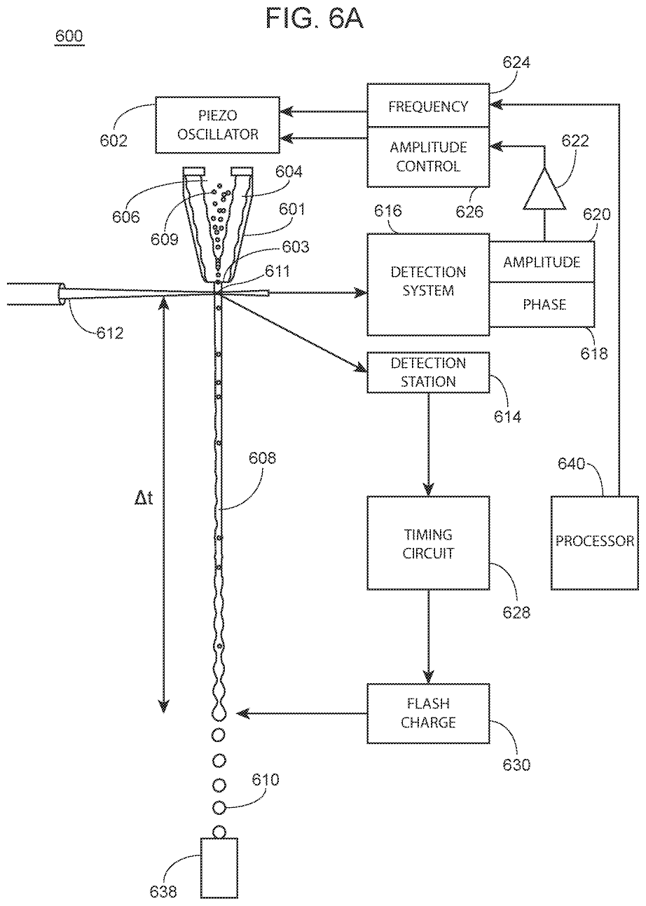

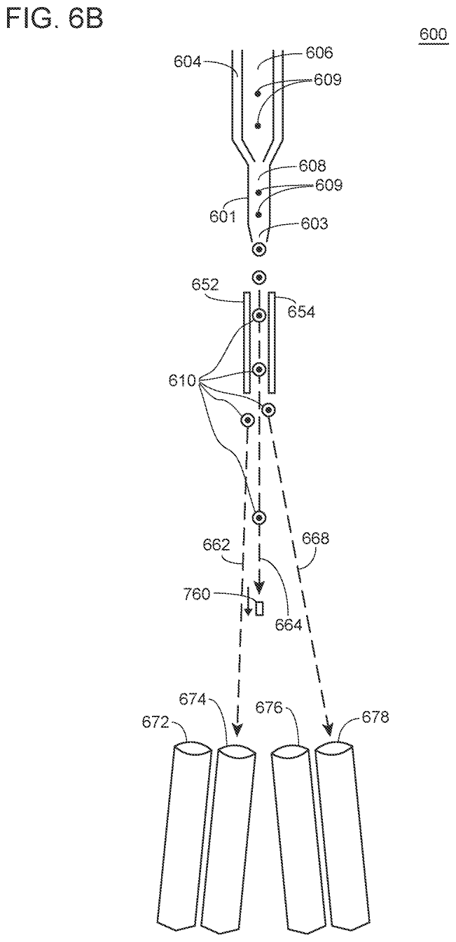

FIG. 6A is a schematic drawing of a particle sorter system 600 (e.g., the particle analyzer or sorting system 502) in accordance with one embodiment presented herein. In some embodiments, the particle sorter system 600 is a cell sorter system. As shown in FIG. 6A, a drop formation transducer 602 (e.g., piezo-oscillator) is coupled to a fluid conduit 601, which can be coupled to, can include, or can be, a nozzle 603. Within the fluid conduit 601, sheath fluid 604 hydrodynamically focuses a sample fluid 606 comprising particles 609 into a moving fluid column 608 (e.g., a stream). Within the moving fluid column 608, particles 609 (e.g., cells) are lined up in single file to cross a monitored area 611 (e.g., where laser-stream intersect), irradiated by an irradiation source 612 (e.g., a laser). Vibration of the drop formation transducer 602 causes moving fluid column 608 to break into a plurality of drops 610, some of which contain particles 609.

In operation, a detection station 614 (e.g., an event detector) identifies when a particle of interest (or cell of interest) crosses the monitored area 611. Detection station 614 feeds into a timing circuit 628, which in turn feeds into a flash charge circuit 630. At a drop break off point, informed by a timed drop delay (Δt), a flash charge can be applied to the moving fluid column 608 such that a drop of interest carries a charge. The drop of interest can include one or more particles or cells to be sorted. The charged drop can then be sorted by activating deflection plates (not shown) to deflect the drop into a vessel such as a collection tube or a multi-well or microwell sample plate where a well or microwell can be associated with drops of particular interest. As shown in FIG. 6A, the drops can be collected in a drain receptacle 638.

A detection system 616 (e.g., a drop boundary detector) serves to automatically determine the phase of a drop drive signal when a particle of interest passes the monitored area 611. An exemplary drop boundary detector is described in U.S. Pat. No. 7,679,039, which is incorporated herein by reference in its entirety. The detection system 616 allows the instrument to accurately calculate the place of each detected particle in a drop. The detection system 616 can feed into an amplitude signal 620 and/or phase 618 signal, which in turn feeds (via amplifier 622) into an amplitude control circuit 626 and/or frequency control circuit 624. The amplitude control circuit 626 and/or frequency control circuit 624, in turn, controls the drop formation transducer 602. The amplitude control circuit 626 and/or frequency control circuit 624 can be included in a control system.

In some implementations, sort electronics (e.g., the detection system 616, the detection station 614 and a processor 640) can be coupled with a memory configured to store the detected events and a sort decision based thereon. The sort decision can be included in the event data for a particle. In some implementations, the detection system 616 and the detection station 614 can be implemented as a single detection unit or communicatively coupled such that an event measurement can be collected by one of the detection system 616 or the detection station 614.

FIG. 6B is a schematic drawing of a particle sorter system, in accordance with one embodiment presented herein. The particle sorter system 600 shown in FIG. 6B, includes deflection plates 652 and 654. A charge can be applied via a stream-charging wire in a barb. This creates a stream of droplets 610 containing particles 610 for analysis. The particles can be illuminated with one or more light sources (e.g., lasers) to generate light scatter and fluorescence information. The information for a particle is analyzed such as by sorting electronics or other detection system (not shown in FIG. 6B). The deflection plates 652 and 654 can be independently controlled to attract or repel the charged droplet to guide the droplet toward a destination collection receptacle (e.g., one of 672, 674, 676, or 678). As shown in FIG. 6B, the deflection plates 652 and 654 can be controlled to direct a particle along a first path 662 toward the receptacle 674 or along a second path 668 toward the receptacle 678. If the particle is not of interest (e.g., does not exhibit scatter or illumination information within a specified sort range), deflection plates may allow the particle to continue along a flow path 664. Such uncharged droplets may pass into a waste receptacle such as via aspirator 670.

The sorting electronics can be included to initiate collection of measurements, receive fluorescence signals for particles, and determine how to adjust the deflection plates to cause sorting of the particles. Example implementations of the embodiment shown in FIG. 6B include the BD FACSAria™ line of flow cytometers commercially provided by Becton, Dickinson and Company (Franklin Lakes, N.J.).

### Methods for Generating a Baseline Restored Signal Over Differential Outputs

As summarized above, aspects of the disclosure also include methods for generating a baseline restored signal over differential outputs by a baseline restoration circuit. Methods according to certain embodiments include receiving by the circuit an input signal originating from a sensor, generating by the circuit based a differential signal based on the input signal, extracting a direct current component of the differential signal, subtracting the extracted direct current component of the differential signal to generate a baseline restored signal, and outputting the resulting baseline restored signal over differential outputs. By “receiving by the circuit,” it is meant transmitting a signal from a sensor, such as a light sensor, for example, a light sensor used in a flow cytometry system, to the circuit, such that the circuit is proximal to the sensor. By “generating a differential signal,” it is meant, for example, applying an amplifier module, such as amplifier modules described herein, to the input signal. By “extracting a direct current component,” it is meant, for example, applying a baseline restoration module, such as baseline restoration modules described herein to the differential signal. By “subtracting the extracted direct current component,” it is meant, for example, feeding back the extracted direct current component of the signal to an amplifier module. By “outputting the resulting baseline restored signal,” it is meant transmitting the baseline restored signal over differential outputs, such as cable core wires as described above.

In embodiments, methods according to the present invention are applied continuously to subtract the direct current component of the input signal that varies slowly over time. In some cases, the direct current component changes over time in part based on a temperature of a sensor generating the input signal.

In embodiments, generating by the circuit a differential signal based on the input signal comprises applying an amplifier configured to generate differential output signals. In other embodiments, extracting a direct current component of the differential signal comprises applying a filter network to the differential signal. In instances, the filter network comprises a low pass filter. In certain cases, the filter network comprises a transconductance element and a capacitor.

In embodiments, subtracting the extracted direct current component of the differential signal comprises feeding the extracted direct current component of the differential signal into a circuit feedback loop. In some embodiments, feeding the extracted a direct current component of the differential signal into a circuit feedback loop comprises feeding the output of an amplifier for generating a differential output signal into an input of the amplifier. In some cases, the input of the amplifier is a non-inverting input of the amplifier.

In embodiments, outputting the resulting baseline restored signal over differential outputs comprises transmitting the baseline restored signal over cable core wires. In some embodiments, the cable core wires are twisted pair wires. In certain embodiments, the cable core wires are shielded.

Aspects of the disclosure also include methods for generating, transmitting and receiving a baseline restored signal over differential outputs. Methods according to certain embodiments include generating by a sensor an input signal, deploying a sensors readout system, such as those described herein, operably connected to the sensor, applying the baseline restoration circuit of the sensors readout system to the input signal to generate a baseline restored differential signal, transmitting by the baseline restoration circuit the baseline restored differential signal over the cable core wires, and receiving by the downstream receiver circuit over the cable core wires the baseline restored differential signal. Certain embodiments further comprise converting by the downstream receiver circuit the baseline restored differential signal into a digital signal. Other embodiments further comprise processing the digital signal to identify events detected by the sensor. Still other embodiments further comprise generating by the downstream receiver circuit a high voltage control potential. Other embodiments further comprise transmitting the high voltage control potential over cable core wires to a sensor for sensor gain control.

In some cases, methods of the present invention are applied in the context of flow cytometry. Methods according to certain embodiments include irradiating with a light source a particle propagating through a flow stream, detecting light from the particles in the sample with a light detection system comprising a light sensor, generating a data signal based on the detected light and generating, from the data signal, a baseline restored signal over differential outputs. In some cases, methods further comprise, transmitting the baseline restored signal over differential outputs to a downstream receiver circuit.

Methods according to certain embodiments include irradiating a particle propagating through the flow stream across an interrogation region of the flow stream of 5 μm or more, such as 10 μm or more, such as 15 μm or more, such as 20 μm or more, such as 25 μm or more, such as 50 μm or more, such as 75 μm or more, such as 100 μm or more, such as 250 μm or more, such as 500 μm or more, such as 750 μm or more, such as for example across an interrogation region of 1 mm or more, such as 2 mm or more, such as 3 mm or more, such as 4 mm or more, such as 5 mm or more, such as 6 mm or more, such as 7 mm or more, such as 8 mm or more, such as 9 mm or more and including 10 mm or more.

In some embodiments, the methods include irradiating the particle in the flow stream with a continuous wave light source, such as where the light source provides uninterrupted light flux and maintains irradiation of particles in the flow stream with little to no undesired changes in light intensity. In some embodiments, the continuous light source emits non-pulsed or non-stroboscopic irradiation. In certain embodiments, the continuous light source provides for substantially constant emitted light intensity. For instance, methods may include irradiating the particle in the flow stream with a continuous light source that provides for emitted light intensity during a time interval of irradiation that varies by 10% or less, such as by 9% or less, such as by 8% or less, such as by 7% or less, such as by 6% or less, such as by 5% or less, such as by 4% or less, such as by 3% or less, such as by 2% or less, such as by 1% or less, such as by 0.5% or less, such as by 0.1% or less, such as by 0.01% or less, such as by 0.001% or less, such as by 0.0001% or less, such as by 0.00001% or less and including where the emitted light intensity during a time interval of irradiation varies by 0.000001% or less.

In other embodiments, the methods include irradiating the particle propagating through the flow stream with a pulsed light source, such as where light is emitted at predetermined time intervals, each time interval having a predetermined irradiation duration (i.e., pulse width). In certain embodiments, methods include irradiating the particle with the pulsed light source in each interrogation region of the flow stream with periodic flashes of light. For example, the frequency of each light pulse may be 0.0001 kHz or greater, such as 0.0005 kHz or greater, such as 0.001 kHz or greater, such as 0.005 kHz or greater, such as 0.01 kHz or greater, such as 0.05 kHz or greater, such as 0.1 kHz or greater, such as 0.5 kHz or greater, such as 1 kHz or greater, such as 2.5 kHz or greater, such as 5 kHz or greater, such as 10 kHz or greater, such as 25 kHz or greater, such as 50 kHz or greater and including 100 kHz or greater. In certain instances, the frequency of pulsed irradiation by the light source ranges from 0.00001 kHz to 1000 kHz, such as from 0.00005 kHz to 900 kHz, such as from 0.0001 kHz to 800 kHz, such as from 0.0005 kHz to 700 kHz, such as from 0.001 kHz to 600 kHz, such as from 0.005 kHz to 500 kHz, such as from 0.01 kHz to 400 kHz, such as from 0.05 kHz to 300 kHz, such as from 0.1 kHz to 200 kHz and including from 1 kHz to 100 kHz. The duration of light irradiation for each light pulse (i.e., pulse width) may vary and may be 0.000001 ms or more, such as 0.000005 ms or more, such as 0.00001 ms or more, such as 0.00005 ms or more, such as 0.0001 ms or more, such as 0.0005 ms or more, such as 0.001 ms or more, such as 0.005 ms or more, such as 0.01 ms or more, such as 0.05 ms or more, such as 0.1 ms or more, such as 0.5 ms or more, such as 1 ms or more, such as 2 ms or more, such as 3 ms or more, such as 4 ms or more, such as 5 ms or more, such as 10 ms or more, such as 25 ms or more, such as 50 ms or more, such as 100 ms or more and including 500 ms or more. For example, the duration of light irradiation may range from 0.000001 ms to 1000 ms, such as from 0.000005 ms to 950 ms, such as from 0.00001 ms to 900 ms, such as from 0.00005 ms to 850 ms, such as from 0.0001 ms to 800 ms, such as from 0.0005 ms to 750 ms, such as from 0.001 ms to 700 ms, such as from 0.005 ms to 650 ms, such as from 0.01 ms to 600 ms, such as from 0.05 ms to 550 ms, such as from 0.1 ms to 500 ms, such as from 0.5 ms to 450 ms, such as from 1 ms to 400 ms, such as from 5 ms to 350 ms and including from 10 ms to 300 ms.

As described above, the particle may be irradiated with any convenient light source and may include laser and non-laser light sources. In certain embodiments, the light source is a non-laser light source, such as a narrow band light source emitting a particular wavelength or a narrow range of wavelengths. In some instances, the narrow band light sources emit light having a narrow range of wavelengths, such as for example, 50 nm or less, such as 40 nm or less, such as 30 nm or less, such as 25 nm or less, such as 20 nm or less, such as 15 nm or less, such as 10 nm or less, such as 5 nm or less, such as 2 nm or less and including light sources which emit a specific wavelength of light (i.e., monochromatic light). Any convenient narrow band light source protocol may be employed, such as a narrow wavelength LED. Any convenient broadband light source protocol may be employed, such as a halogen lamp, deuterium arc lamp, xenon arc lamp, stabilized fiber-coupled broadband light source, a broadband LED with continuous spectrum, superluminescent emitting diode, semiconductor light emitting diode, wide spectrum LED white light source, a multi-LED integrated white light source, among other broadband light sources or any combination thereof. In certain embodiments, light sources include an array of LEDs. In certain instances, the light source includes a plurality of monochromatic light emitting diodes where each monochromatic light emitting diode outputs light having a different wavelength. In some instances, the light source includes a plurality of polychromatic light emitting diodes outputting light having a predetermined spectral width, such as where the plurality of polychromatic light emitting diodes collectively output light having a spectral width that ranges from 200 nm to 1500 nm, such as from 225 nm to 1475 nm, such as from 250 nm to 1450 nm, such as from 275 nm to 1425 nm, such as from 300 nm to 1400 nm, such as from 325 nm to 1375 nm, such as from 350 nm to 1350 nm, such as from 375 nm to 1325 nm, such as from 400 nm to 1300 nm, such as from 425 nm to 1275 nm, such as from 450 nm to 1250 nm, such as from 475 nm to 1225 nm and including from 500 nm to 1200 nm.

In certain embodiments, methods include irradiating the particle with a laser, such as a pulsed or continuous wave laser. For example, the laser may be a diode laser, such as an ultraviolet diode laser, a visible diode laser and a near-infrared diode laser. In other embodiments, the laser may be a helium-neon (HeNe) laser. In some instances, the laser is a gas laser, such as a helium-neon laser, argon laser, krypton laser, xenon laser, nitrogen laser, CO₂ laser, CO laser, argon-fluorine (ArF) excimer laser, krypton-fluorine (KrF) excimer laser, xenon chlorine (XeCl) excimer laser or xenon-fluorine (XeF) excimer laser or a combination thereof. In other instances, the subject systems include a dye laser, such as a stilbene, coumarin or rhodamine laser. In yet other instances, lasers of interest include a metal-vapor laser, such as a helium-cadmium (HeCd) laser, helium-mercury (HeHg) laser, helium-selenium (HeSe) laser, helium-silver (HeAg) laser, strontium laser, neon-copper (NeCu) laser, copper laser or gold laser and combinations thereof. In still other instances, the subject systems include a solid-state laser, such as a ruby laser, an Nd:YAG laser, NdCrYAG laser, Er:YAG laser, Nd:YLF laser, Nd:YVO₄ laser, Nd:YCa₄O(BO₃)₃ laser, Nd:YCOB laser, titanium sapphire laser, thulim YAG laser, ytterbium YAG laser, ytterbium₂O₃ laser or cerium doped lasers and combinations thereof.

The particle in the flow stream may be irradiated by the light source from any suitable distance, such as at a distance of 0.001 mm or more, such as 0.005 mm or more, such as 0.01 mm or more, such as 0.05 mm or more, such as 0.1 mm or more, such as 0.5 mm or more, such as 1 mm or more, such as 5 mm or more, such as 10 mm or more, such as 25 mm or more and including at a distance of 100 mm or more. In addition, irradiation of the flow stream may be at any suitable angle such as at an angle ranging from 10° to 90°, such as from 15° to 85°, such as from 20° to 80°, such as from 25° to 75° and including from 30° to 60°, for example at a 90° angle.

In practicing the subject methods, light from the irradiated particle is continuously conveyed to a sensor, in some cases, through a light adjustment component, as the particle is propagated through the flow stream. In some instances, light conveyed from the irradiated particle is emitted light such as fluorescence from the particle. In some instances, light conveyed from the irradiated particle is scattered light. In some cases, the scattered light is forward scattered light. In some cases, the scattered light is backscattered light. In some cases, the scattered light is side scattered light. In some instances, light conveyed from the irradiated particle is transmitted light.

The light adjustment component may be any convenient optical protocol for collecting and propagating light from the particle to a sensor. In some embodiments, the light adjustment component collimates the light collected from the particle and conveys collimated light to the sensor. In some embodiments, the light adjustment component conveys incident light from the irradiated particle to the sensor at an angle that varies from 60° to 90° relative to the surface of the birefringent polarizing interferometer, such as from 65° to 90°, such as from 70° to 90°, such as from 75° to 90°, 80° to 90° and including from 85° to 90° relative to the surface of the birefringent polarizing interferometer. In certain embodiments, the light adjustment component conveys perpendicularly incident light from the irradiated particle to the sensor.

The light adjustment component may be any convenient optical protocol for collecting and continuously conveying light from the particle propagating through the flow stream. In some embodiments, the light adjustment component includes a compound lens. In certain embodiments, the light adjustment component includes a compound lens and one or more aperture stops, such as where the one or more aperture stops are positioned in the light adjustment component at the focal points of the compounds lens. The light adjustment component in certain instances includes a telecentric lens. In some instances, the light adjustment component includes an object-space telecentric lens. In some instances, the light adjustment component includes an image-space telecentric lens. In certain instances, the light adjustment component includes a double telecentric lens (e.g., a bi-telecentric lens).

In embodiments, light from the irradiated particle is conveyed to a photodetector. In some embodiments, light is detected with one or more photodetectors, such as 2 or more, such as 3 or more, such as 4 or more, such as 5 or more, such as 6 or more, such as 7 or more, such as 8 or more, such as 9 or more and including 10 or more photodetectors. Photodetectors for practicing the subject methods may be any convenient light detecting protocol, including but not limited to photosensors or photodetectors, such as active-pixel sensors (APSs), quadrant photodiodes, image sensors, charge-coupled devices (CCDs), intensified charge-coupled devices (ICCDs), light emitting diodes, photon counters, bolometers, pyroelectric detectors, photoresistors, photovoltaic cells, photodiodes, photomultiplier tubes, phototransistors, quantum dot photoconductors or photodiodes and combinations thereof, among other photodetectors. In certain embodiments, the photodetector is a photomultiplier tube, such as a photomultiplier tube having an active detecting surface area of each region that ranges from 0.01 cm² to 10 cm², such as from 0.05 cm² to 9 cm², such as from, such as from 0.1 cm² to 8 cm², such as from 0.5 cm² to 7 cm² and including from 1 cm² to 5 cm².

Light may be measured by the photodetector at one or more wavelengths, such as at 2 or more wavelengths, such as at 5 or more different wavelengths, such as at 10 or more different wavelengths, such as at 25 or more different wavelengths, such as at 50 or more different wavelengths, such as at 100 or more different wavelengths, such as at 200 or more different wavelengths, such as at 300 or more different wavelengths and including measuring light from particles in the flow stream at 400 or more different wavelengths. Light may be measured continuously or in discrete intervals. In some instances, detectors of interest are configured to take measurements of the light continuously. In other instances, detectors of interest are configured to take measurements in discrete intervals, such as measuring light every 0.001 millisecond, every 0.01 millisecond, every 0.1 millisecond, every 1 millisecond, every 10 milliseconds, every 100 milliseconds and including every 1000 milliseconds, or some other interval.

Measurements of the light from the light source may be taken one or more times during each discrete time interval, such as 2 or more times, such as 3 or more times, such as 5 or more times and including 10 or more times. In certain embodiments, the light from the light source is measured by the photodetector 2 or more times, with the data in certain instances being averaged.

In some embodiments, light detected from each particle in the sample is emitted light, such as particle luminescence (i.e., fluorescence or phosphorescence). In these embodiments, each particle may include one or more fluorophores which emits fluorescence in response to irradiation by the two or more light sources. For example, each particle may include 2 or more fluorophores, such as 3 or more, such as 4 or more, such as 5 or more, such as 6 or more, such as 7 or more, such as 8 or more, such as 9 or more and including 10 or more fluorophores. In some instances, each particle includes a fluorophore which emits fluorescence in response to irradiation by the light source. In some embodiments, fluorophores of interest may include but are not limited to dyes suitable for use in analytical applications (e.g., flow cytometry, imaging, etc.), such as an acridine dye, anthraquinone dyes, arylmethane dyes, diarylmethane dyes (e.g., diphenyl methane dyes), chlorophyll containing dyes, triarylmethane dyes (e.g., triphenylmethane dyes), azo dyes, diazonium dyes, nitro dyes, nitroso dyes, phthalocyanine dyes, cyanine dyes, asymmetric cyanine dyes, quinon-imine dyes, azine dyes, eurhodin dyes, safranin dyes, indamins, indophenol dyes, fluorine dyes, oxazine dye, oxazone dyes, thiazine dyes, thiazole dyes, xanthene dyes, fluorene dyes, pyronin dyes, fluorine dyes, rhodamine dyes, phenanthridine dyes, as well as dyes combining two or more of the aforementioned dyes (e.g., in tandem), polymeric dyes having one or more monomeric dye units and mixtures of two or more of the aforementioned dyes thereof. A large number of dyes are commercially available from a variety of sources, such as, for example, Molecular Probes (Eugene, Oreg.), Dyomics GmbH (Jena, Germany), Sigma-Aldrich (St. Louis, Mo.), Sirigen, Inc. (Santa Barbara, Calif.) and Exciton (Dayton, Ohio). For example, the fluorophore may include 4-acetamido-4′-isothiocyanatostilbene-2,2′disulfonic acid; acridine and derivatives such as acridine, acridine orange, acridine yellow, acridine red, and acridine isothiocyanate; allophycocyanin, phycoerythrin, peridinin-chlorophyll protein, 5-(2′-aminoethyl)aminonaphthalene-1-sulfonic acid (EDANS); 4-amino-N-[3-vinylsulfonyl)phenyl]naphthalimide-3,5 disulfonate (Lucifer Yellow VS); N-(4-anilino-1-naphthyl)maleimide; anthranilamide; Brilliant Yellow; coumarin and derivatives such as coumarin, 7-amino-4-methylcoumarin (AMC, Coumarin 120), 7-amino-4-trifluoromethylcouluarin (Coumaran 151); cyanine and derivatives such as cyanosine, Cy3, Cy3.5, Cy5, Cy5.5, and Cy7; 4′,6-diaminidino-2-phenylindole (DAPI); 5′, 5″-dibromopyrogallol-sulfonephthalein (Bromopyrogallol Red); 7-diethylamino-3-(4′-isothiocyanatophenyl)-4-methylcoumarin; diethylaminocoumarin; diethylenetriamine pentaacetate; 4,4′-diisothiocyanatodihydro-stilbene-2,2′-disulfonic acid; 4,4′-diisothiocyanatostilbene-2,2′-disulfonic acid; 5-[dimethylamino]naphthalene-1-sulfonyl chloride (DNS, dansyl chloride); 4-(4′-dimethylaminophenylazo)benzoic acid (DABCYL); 4-dimethylaminophenylazophenyl-4′-isothiocyanate (DABITC); eosin and derivatives such as eosin and eosin isothiocyanate; erythrosin and derivatives such as erythrosin B and erythrosin isothiocyanate; ethidium; fluorescein and derivatives such as 5-carboxyfluorescein (FAM), 5-(4,6-dichlorotriazin-2-yl)aminofluorescein (DTAF), 2′7′-dimethoxy-4′5′-dichloro-6-carboxyfluorescein (JOE), fluorescein isothiocyanate (FITC), fluorescein chlorotriazinyl, naphthofluorescein, and QFITC (XRITC); fluorescamine; IR144; IR1446; Green Fluorescent Protein (GFP); Reef Coral Fluorescent Protein (RCFP); Lissamine™; Lissamine rhodamine, Lucifer yellow; Malachite Green isothiocyanate; 4-methylumbelliferone; ortho cresolphthalein; nitrotyrosine; pararosaniline; Nile Red; Oregon Green; Phenol Red; B-phycoerythrin; o-phthaldialdehyde; pyrene and derivatives such as pyrene, pyrene butyrate and succinimidyl 1-pyrene butyrate; Reactive Red 4 (Cibacron™ Brilliant Red 3B-A); rhodamine and derivatives such as 6-carboxy-X-rhodamine (ROX), 6-carboxyrhodamine (R6G), 4,7-dichlororhodamine lissamine, rhodamine B sulfonyl chloride, rhodamine (Rhod), rhodamine B, rhodamine 123, rhodamine X isothiocyanate, sulforhodamine B, sulforhodamine 101, sulfonyl chloride derivative of sulforhodamine 101 (Texas Red), N,N,N′,N′-tetramethyl-6-carboxyrhodamine (TAMRA), tetramethyl rhodamine, and tetramethyl rhodamine isothiocyanate (TRITC); riboflavin; rosolic acid and terbium chelate derivatives; xanthene; dye-conjugated polymers (i.e., polymer-attached dyes) such as fluorescein isothiocyanate-dextran as well as dyes combining two or more dyes (e.g., in tandem), polymeric dyes having one or more monomeric dye units and mixtures of two or more of the aforementioned dyes or combinations thereof.

In some instances, the fluorophore is polymeric dye. In some instances of the method, the polymeric dye includes a conjugated polymer. Conjugated polymers (CPs) are characterized by a delocalized electronic structure which includes a backbone of alternating unsaturated bonds (e.g., double and/or triple bonds) and saturated (e.g., single bonds) bonds, where π-electrons can move from one bond to the other. As such, the conjugated backbone may impart an extended linear structure on the polymeric dye, with limited bond angles between repeat units of the polymer. For example, proteins and nucleic acids, although also polymeric, in some cases do not form extended-rod structures but rather fold into higher-order three-dimensional shapes. In addition, CPs may form “rigid-rod” polymer backbones and experience a limited twist (e.g., torsion) angle between monomer repeat units along the polymer backbone chain. In some instances, the polymeric dye includes a CP that has a rigid rod structure. The structural characteristics of the polymeric dyes can have an effect on the fluorescence properties of the molecules. Polymeric dyes of interest include, but are not limited to, those dyes described by Gaylord et al. in U.S. Publication Nos. 20040142344, 20080293164, 20080064042, 20100136702, 20110256549, 20110257374, 20120028828, 20120252986, 20130190193, 20160264737, 20160266131, 20180231530, 20180009990, 20180009989, and 20180163054, the disclosures of which are herein incorporated by reference in their entirety; and Gaylord et al., J. Am. Chem. Soc., 2001, 123 (26), pp 6417-6418; Feng et al., Chem. Soc. Rev., 2010, 39, 2411-2419; and Traina et al., J. Am. Chem. Soc., 2011, 133 (32), pp 12600-12607, the disclosures of which are herein incorporated by reference in their entirety.

The polymeric dye may have one or more desirable spectroscopic properties, such as a particular absorption maximum wavelength, a particular emission maximum wavelength, extinction coefficient, quantum yield, and the like (see e.g., Chattopadhyay et al., “Brilliant violet fluorophores: A new class of ultrabright fluorescent compounds for immunofluorescence experiments.” Cytometry Part A, 81A(6), 456-466, 2012). In some embodiments, the polymeric dye has an absorption curve between 280 nm and 475 nm. In certain embodiments, the polymeric dye has an absorption maximum (excitation maximum) in the range 280 nm and 475 nm. In some embodiments, the polymeric dye absorbs incident light having a wavelength in the range between 280 nm and 475 nm. In some embodiments, the polymeric dye has an emission maximum wavelength ranging from 400 nm to 850 nm, such as 415 nm to 800 nm, where specific examples of emission maxima of interest include, but are not limited to: 421 nm, 510 nm, 570 nm, 602 nm, 650 nm, 711 nm and 786 nm. In some instances, the polymeric dye has an emission maximum wavelength in a range selected from the group consisting of 410 nm to 430 nm, 500 nm to 520 nm, 560 nm to 580 nm, 590 nm to 610 nm, 640 nm to 660 nm, 700 nm to 720 nm, and 775 nm to 795 nm. In certain embodiments, the polymeric dye has an emission maximum wavelength of 421 nm. In some instances, the polymeric dye has an emission maximum wavelength of 510 nm. In some cases, the polymeric dye has an emission maximum wavelength of 570 nm. In certain embodiments, the polymeric dye has an emission maximum wavelength of 602 nm. In some instances, the polymeric dye has an emission maximum wavelength of 650 nm. In certain cases, the polymeric dye has an emission maximum wavelength of 711 nm. In some embodiments, the polymeric dye has an emission maximum wavelength of 786 nm. In certain instances, the polymeric dye has an emission maximum wavelength of 421 nm±5 nm. In some embodiments, the polymeric dye has an emission maximum wavelength of 510 nm±5 nm. In certain instances, the polymeric dye has an emission maximum wavelength of 570 nm±5 nm. In some instances, the polymeric dye has an emission maximum wavelength of 602 nm±5 nm. In some embodiments, the polymeric dye has an emission maximum wavelength of 650 nm±5 nm. In certain instances, the polymeric dye has an emission maximum wavelength of 711 nm±5 nm. In some cases, the polymeric dye has an emission maximum wavelength of 786 nm±5 nm. In certain embodiments, the polymeric dye has an emission maximum selected from the group consisting of 421 nm, 510 nm, 570 nm, 602 nm, 650 nm, 711 nm and 786 nm.

Specific polymeric dyes that may be employed include, but are not limited to, BD Horizon Brilliant™ Dyes, such as BD Horizon Brilliant™ Violet Dyes (e.g., BV421, BV510, BV605, BV650, BV711, BV786); BD Horizon Brilliant™ Ultraviolet Dyes (e.g., BUV395, BUV496, BUV737, BUV805); and BD Horizon Brilliant™ Blue Dyes (e.g., BB515) (BD Biosciences, San Jose, Calif.).

In certain embodiments, light conveyed from the irradiated particle is scattered light. The term “scattered light” is used herein in its conventional sense to refer to the propagation of light energy from the particle that are deflected from the incident beam path, such as by reflection, refraction or deflection of the beam of light. In certain instances, scattered light detected from the particle in the flow stream is forward scattered light (FSC). In other instances, scattered light detected from the particles in the flow stream is side scattered light. In yet other instances, scattered light detected from the particles in the flow stream is back-scattered light.

Light conveyed from the irradiated particle as the particle is propagated through the flow stream may be detected in one or more photodetector channels, such as 2 or more, such as 3 or more, such as 4 or more, such as 5 or more, such as 6 or more, such as 7 or more, such as 8 or more, such as 9 or more and including 10 or more photodetector channels. In some embodiments, ranges of wavelengths of light conveyed from the irradiated particle as the particle is propagated through the flow stream are detected in different photodetector channels, such as where each range of wavelengths is detected in a distinct photodetector channel.

In certain embodiments, methods also include sorting the particle. The term “sorting” is used herein in its conventional sense to refer to separating components (e.g., droplets containing cells, droplets containing non-cellular particles such as biological macromolecules) of a sample and in some instances, delivering the separated components to one or more sample collection containers. For example, methods may include sorting 2 or more components of a sample, such as 3 or more components, such as 4 or more components, such as 5 or more components, such as 10 or more components, such as 15 or more components and including sorting 25 or more components of the sample. In embodiments, methods including sorting cells based on the photodetector signal pulse.

A particular subpopulation of interest may then further analyzed by “gating” based on the data collected for the entire population. To select an appropriate gate, the data is plotted so as to obtain the best separation of subpopulations possible. This procedure may be performed by plotting forward light scatter (FSC) vs. side (i.e., orthogonal) light scatter (SSC) on a two-dimensional dot plot. A subpopulation of particles is then selected (i.e., those cells within the gate) and particles that are not within the gate are excluded. Where desired, the gate may be selected by drawing a line around the desired subpopulation using a cursor on a computer screen. Only those particles within the gate are then further analyzed by plotting the other parameters for these particles, such as fluorescence. Where desired, the above analysis may be configured to yield counts of the particles of interest in the sample.

In some embodiments, methods include sorting components of a sample, such as described in U.S. Pat. Nos. 10,006,852; 9,952,076; 9,933,341; 9,784,661; 9,726,527; 9,453,789; 9,200,334; 9,097,640; 9,095,494; 9,092,034; 8,975,595; 8,753,573; 8,233,146; 8,140,300; 7,544,326; 7,201,875; 7,129,505; 6,821,740; 6,813,017; 6,809,804; 6,372,506; 5,700,692; 5,643,796; 5,627,040; 5,620,842; 5,602,039; the disclosures of which are herein incorporated by reference in their entirety. In some embodiments, methods for sorting components of sample include sorting particles (e.g., cells in a biological sample) with an enclosed particle sorting module, such as those described in U.S. Patent Publication No. 2017/0299493, the disclosure of which is incorporated herein by reference. In certain embodiments, particles (e.g., cells) of the sample are sorted using a sort decision module having a plurality of sort decision units, such as those described in U.S. Patent Publication No. 2020/0256781, the disclosure of which is incorporated herein by reference. In some embodiments, methods for sorting components of sample include sorting particles (e.g., cells in a biological sample) with a particle sorting module having deflector plates, such as described in U.S. Patent Publication No. 2017/0299493, filed on Mar. 28, 2017, the disclosure of which is incorporated herein by reference.

### Utility

The subject circuits, systems and methods find use in a variety of applications where it is desirable to optimize sensor functionality, for example in the context of particle identification, characterization and sorting. The subject circuits, systems and methods provide for identifying or characterizing a particle in a flow stream. The present disclosure also finds use in flow cytometry where it is desirable to provide a flow cytometer with improved cell sorting accuracy, enhanced particle collection, reduced energy consumption, particle charging efficiency, more accurate particle charging and enhanced particle deflection during cell sorting. In embodiments, the present disclosure reduces the need for user input or manual adjustment during sample analysis with a flow cytometer. In certain embodiments, the subject methods and systems provide fully automated protocols so that adjustments to a flow cytometer during use require little, if any human input.

The following example(s) is/are offered by way of illustration and not by way of limitation.

### EXAMPLES

### Baseline Restoration Circuits:

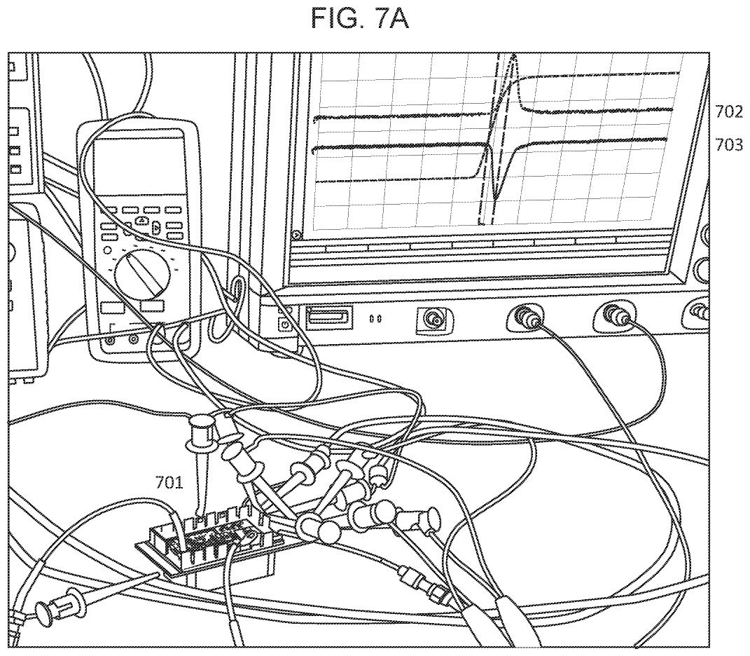

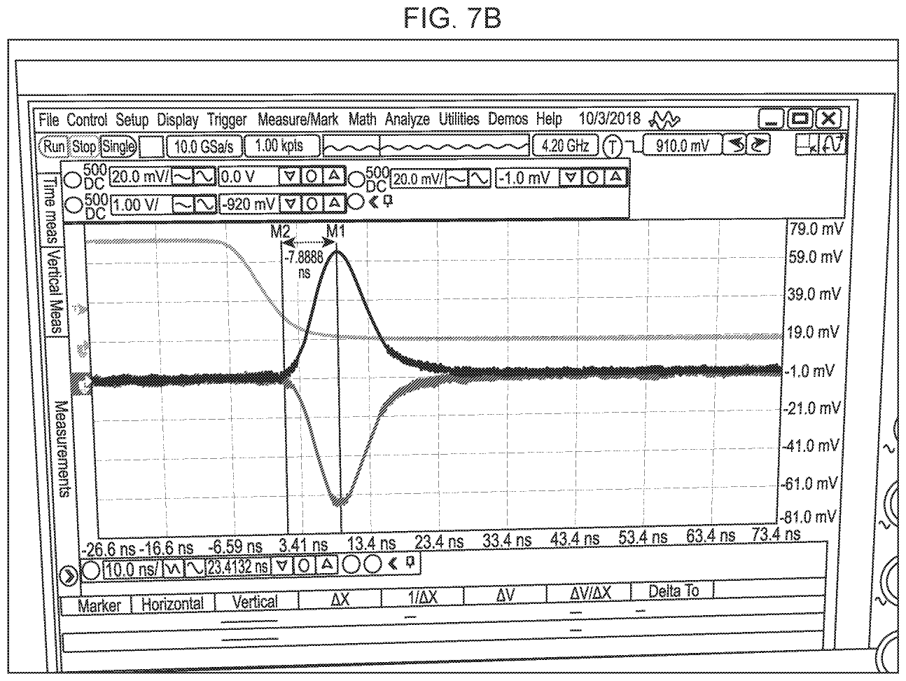

FIG. 7A provides a picture of aspects of a baseline restoration circuit 701 with differential outputs as depicted in FIGS. 1A-1B according to an embodiment of the invention, including a readout of the baseline restored response on differential outputs 702, 703. FIG. 7B provides another view of the readout delta response on differential outputs of baseline restoration circuit 701.

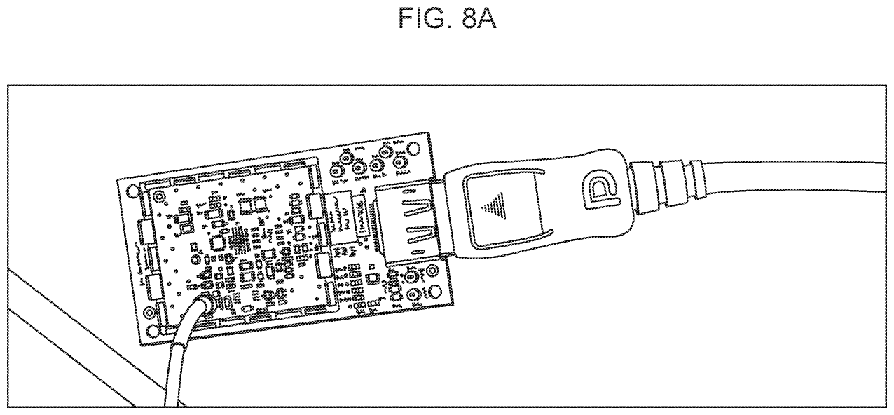

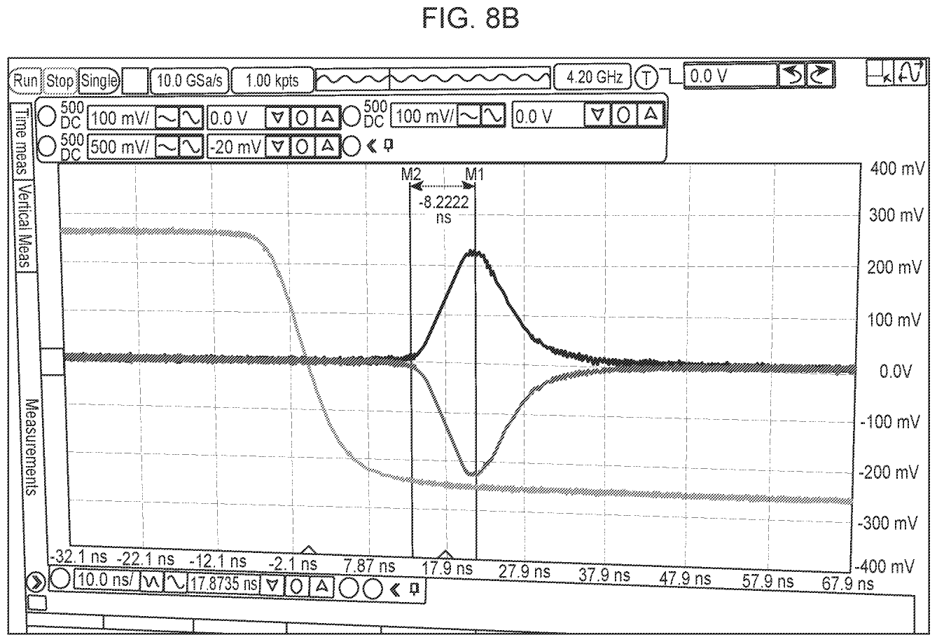

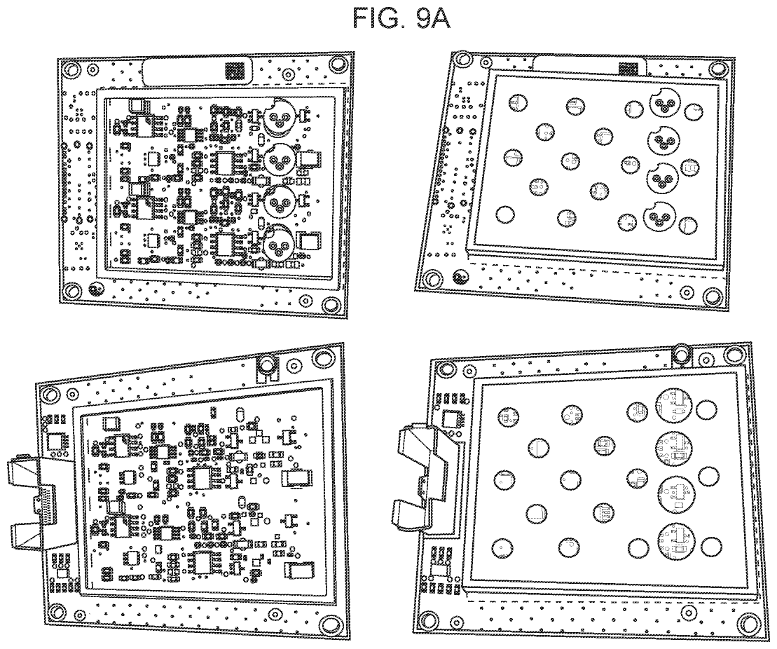

FIG. 8A provides another view of aspects of a baseline restoration circuit with differential outputs for use with photodiode sensors as depicted in FIGS. 1A-1B according to an embodiment of the invention. FIG. 8B provides another view of the readout delta response on differential outputs of baseline restoration circuit implemented on the board shown in FIG. 8A.

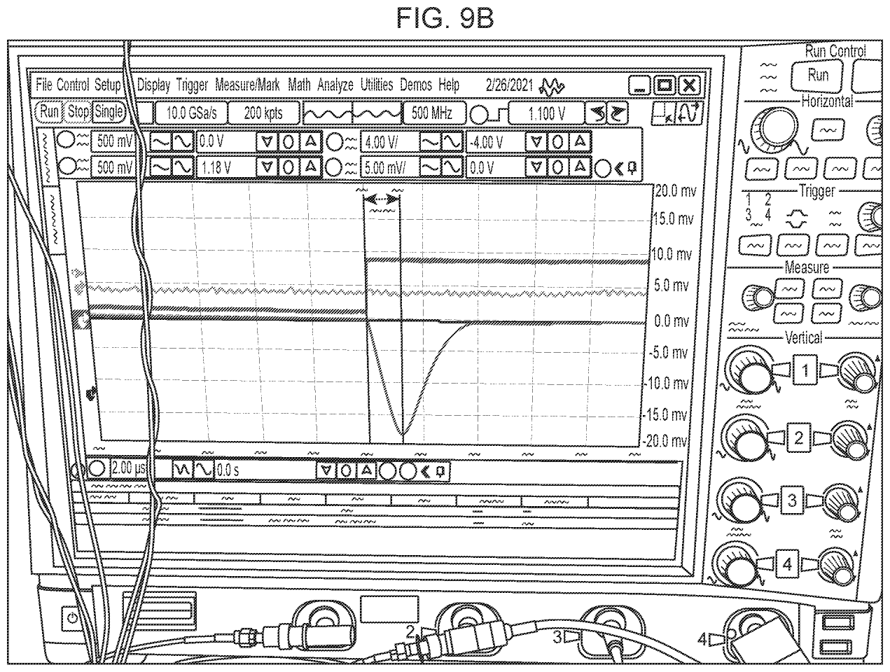

FIG. 9A provides a picture of aspects of a baseline restoration circuit with differential outputs for use with APD sensors as depicted in FIGS. 2A-2B according to an embodiment of the invention. FIG. 9B provides a view of the readout of the delta response of subtracted differential outputs of baseline restoration circuit implemented on the board shown in FIG. 9A.

### Sensors Readout Systems:

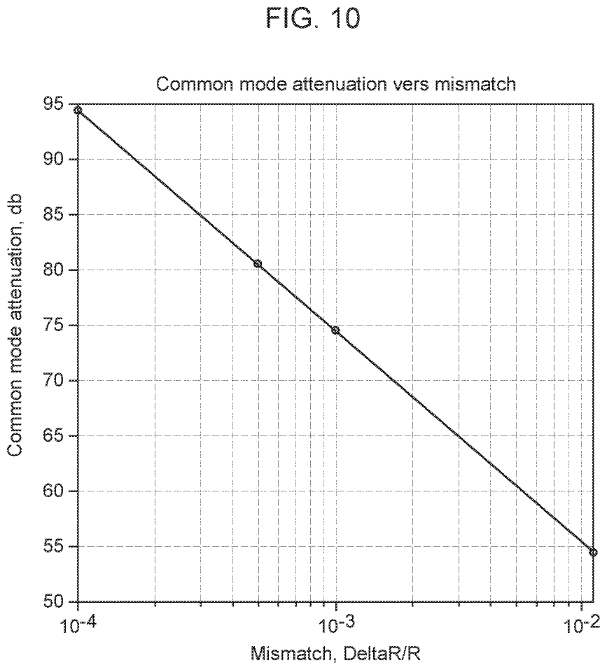

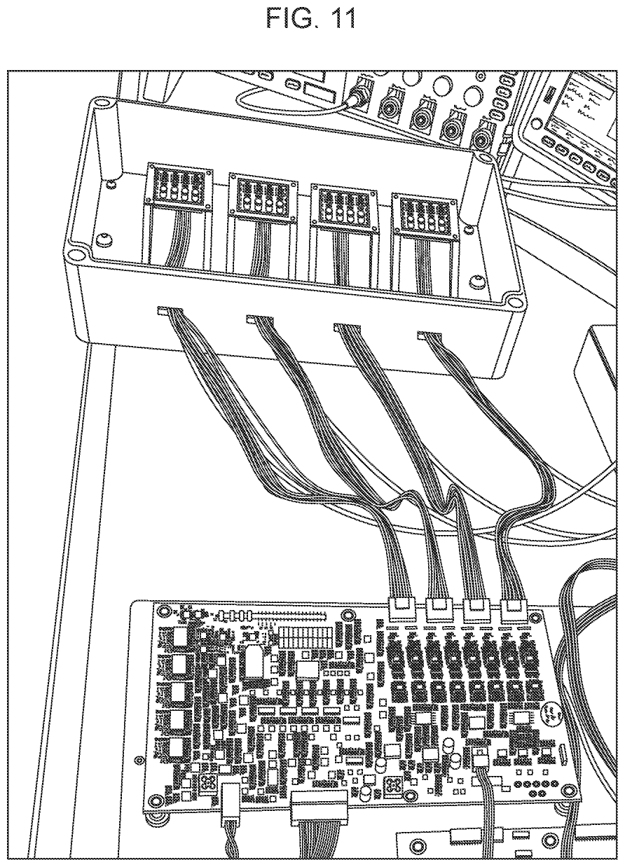

As described in detail above, downstream receiver circuit of sensors readout systems of the present invention include an anti-alias filter for use in connection with sampling input signals ultimately received from sensors, such as light sensors. Both imaging and spectrometry applications of flow cytometry require a large dynamic range and as a result, the matching of the differential circuit components in the anti-alias filter module 310 shown in FIGS. 3A-3B is very important for signal integrity. To this end, FIG. 10 shows results of a Monte-Carlo simulated result of the common mode signal attenuation as a function of the anti-alias filter resistors mismatch. The differential and the common mode signals of the same magnitude are assumed, the filter was configured to the bandwidth f_{-3db}=400 KHz. It is shown in FIG. 10 that reaching the attenuation of more than 80 db for the common mode signal of the same magnitude as the full scale differential signal requires less than 0.05% resistor tolerance.

FIG. 11 depicts one embodiment of a sensors readout system implemented in the context of a flow cytometer readout with 16 sensors, in this case, avalanche photo diode, i.e., APD, channels that uses cabling and circuit configurations according to the invention. The analog front-end is represented by four boards with four APD readout channels at each board. Four APD boards are read out by one acquisition board to which the APD readout front-end boards are cabled. The acquisition board includes an embodiment of a downstream receiver circuit in accordance with the present invention, the functionality of which is described, for example, in connection with FIGS. 3A-3B.

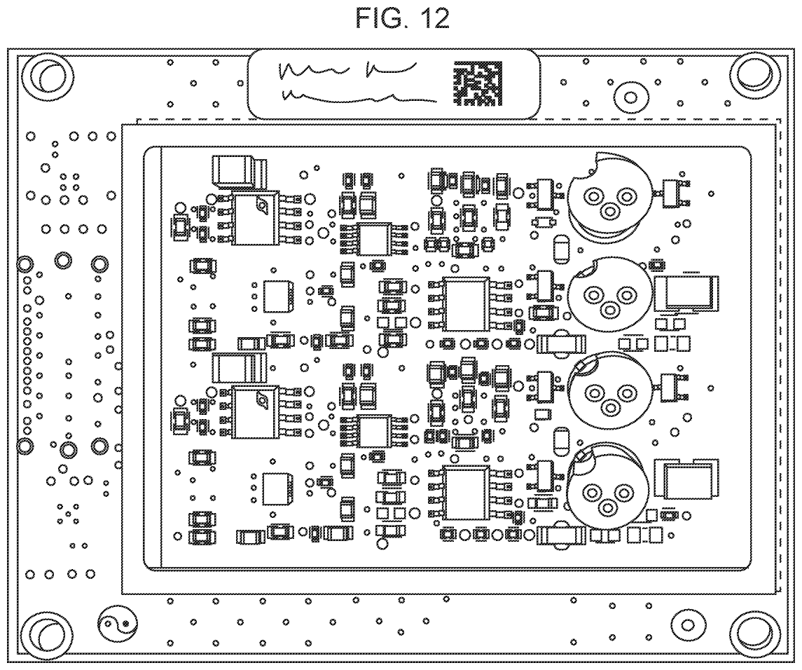

FIG. 12 depicts an embodiment of one front-end board to read out the APDs that corresponds to the front-end baseline restoration circuit 200 shown in FIG. 2A-2B. The three pin sockets of FIG. 12 allow flexibility for changing the APD types when adapting the readout system, i.e., downstream receiver circuit, to the required configuration. Cabling that supports the system functionality is implemented with two core wires inside shields 145 shown in FIGS. 1A-1B and 245 shown in FIGS. 2A-2B. Stranded cores type is preferred when connecting the ‘H.V.’ voltages 396 to the APDs to set the gain control.

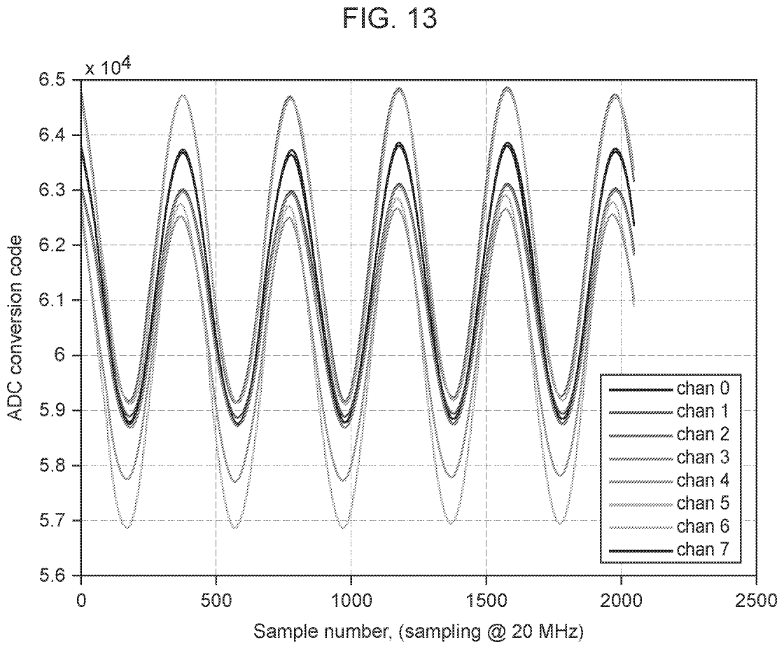

Electric characteristics for the sensors readout system were measured with the ADC clock 334 set at 20 MHz using equivalent capacitors of 10 pF inserted in the APD insertion sockets. FIG. 13 shows the full system response to the current stimuli of 200 KHz sinewaves injected into each channel via calibration capacitances.

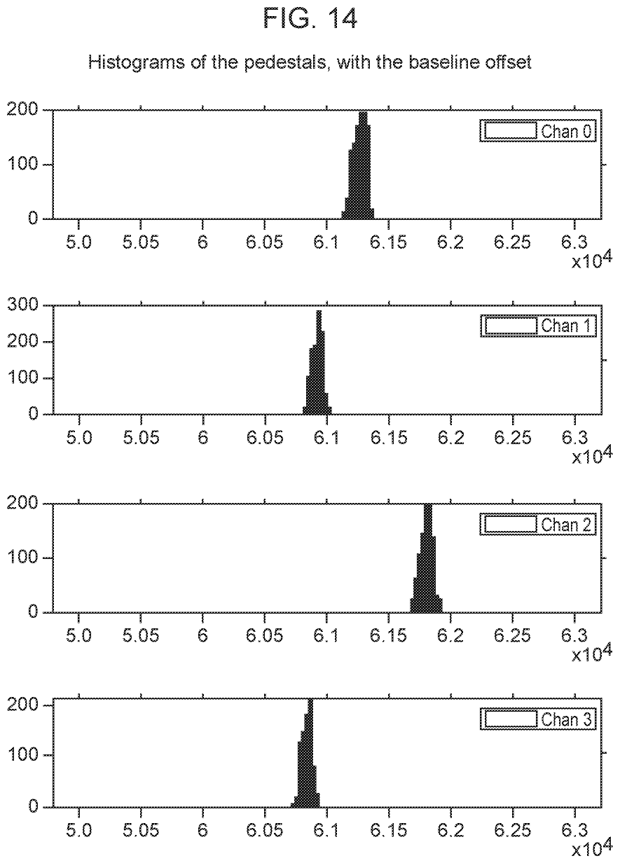

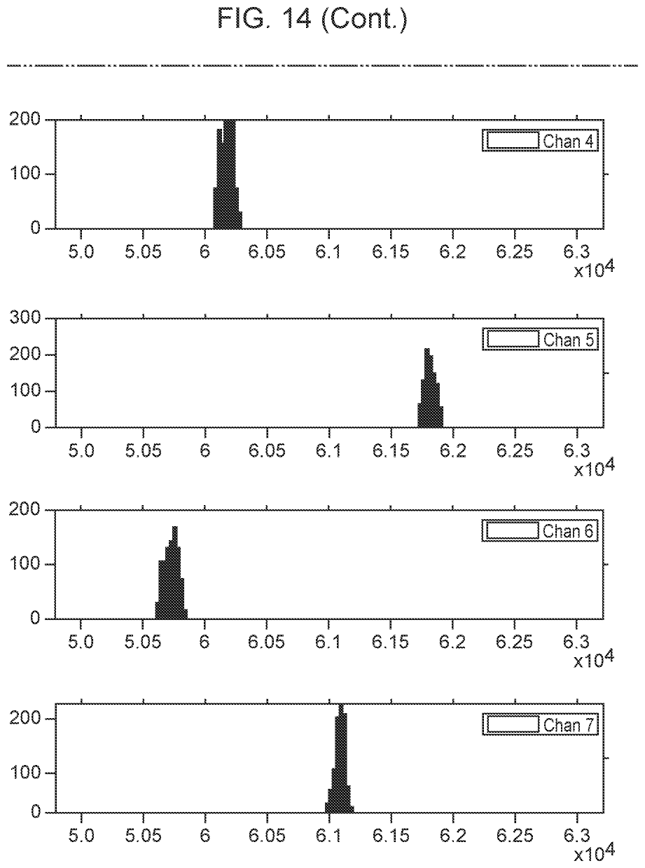

In connection with examining the full system response, the pedestal offsets were pulled towards the highest 16 bit ADC conversion code of 65,536 counts to allow the wide swing of the detected photocurrent (from 2¹⁶ to 0 counts) to be digitized when the readout is used with the APDs. FIG. 14 shows the ADC pedestals, i.e., amplitude distributions when no signal is present measured with the offsets of FIG. 13.

In the frequency domain the transfer function for the full readout (the readout trans-conductance) of a downstream receiver circuit was measured by injection of sinewaves having different frequencies as compare with the front-end inputs to the baseline restoration circuit/sensors. The bandwidth of f_{-3db}=300 KHz was measured in an embodiment of the system depicted in FIGS. 3A-3B. Using the above measurement results, the in-band current noise of the full acquisition system, i.e., a sensors readout system according to the present invention, was evaluated using expression below.

Equivalent input current noise:

$${i}_{noise} = \sqrt{〈 {i}^{2} 〉 - {〈 i 〉}^{2}} = \frac{{σ}_{pedestal}}{{signal}_{p k - p k}} \frac{{i}_{stim}}{\sqrt{OSR}} , \\ OSR - oversampling ratio , \\ {σ}_{pedestal} - baseline standard deviation \\ {signal}_{p k - p k} - calibration current pk - pk$$

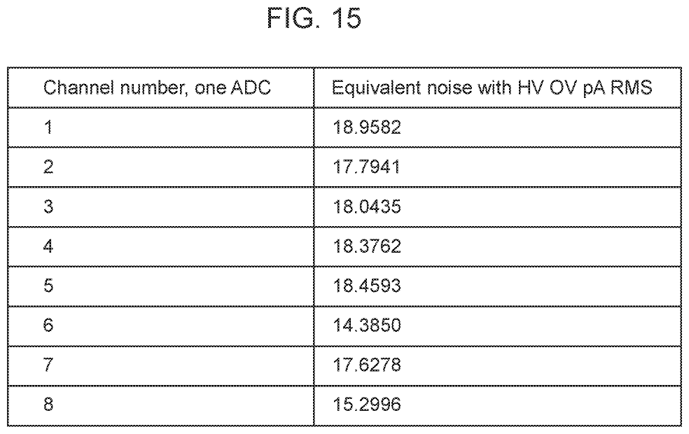

Using an ADC 331 clock 334 frequency of 20 MHz, the oversampling ratio of 33.33=20 MHz/(2×0.3 MHz) is used in the evaluation. FIG. 15 depicts a table showing the results of the equivalent noise current measurements.

With low sensor, i.e., APD, gain (less than 50) and low excess noise factor of the APDs, the equivalent noise power about 1-2 pW was measured for the APD readout described above.

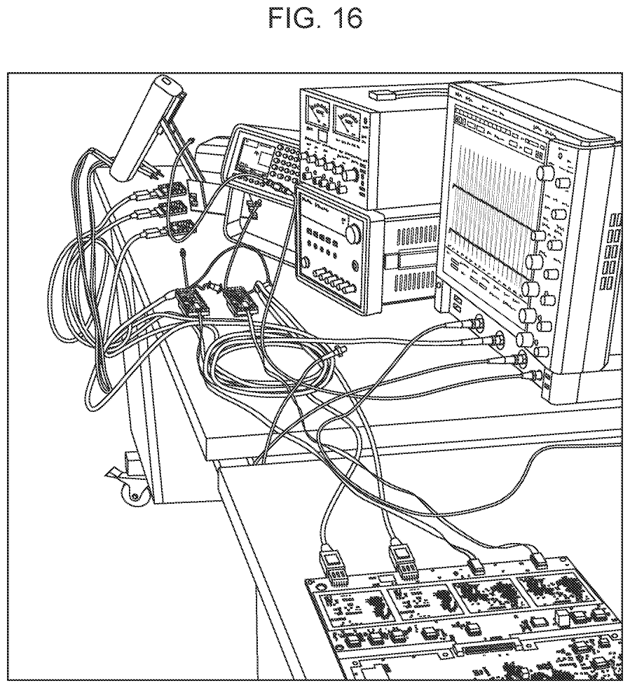

FIG. 16 shows embodiments of sensors readout systems according to the present invention. In particular, remote operation of photodiode (PD) and photomultiplier tube (PMT) front-end readout channels (i.e., sensors coupled to baseline restoration circuits with differential outputs according to the present invention) with the acquisition board (i.e., downstream receiver circuit) using different length and types of multicore cables connecting the front-ends (baseline restoration circuits) to the acquisition board (downstream receiver circuit) are depicted. The front-end readout circuits correspond to the schema shown in FIGS. 1A-1B. The operational bandwidth for the readout channels in this subsystem is f_{-3db}=80 MHz.

Few cable types were utilized in different flow cytometer subsystems with the type of the readout described adapted for each subsystem. The subsystems represent, but are not be limited to, the photodiode readout of the forward scatter and the bright channels, photomultiplier imaging and APD spectrometer readouts of a flow cytometer system. The cable length ranging from one to six feet was successfully implemented in above subsystems. The multi-wire multicores cables are commercially available products of a type produced for fiber optics communication and high-definition television markets.

Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims.

Accordingly, the preceding merely illustrates the principles of the invention. It will be appreciated that those skilled in the art will be able to devise various arrangements which, although not explicitly described or shown herein, embody the principles of the invention and are included within its spirit and scope. Furthermore, all examples and conditional language recited herein are principally intended to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. Moreover, nothing disclosed herein is intended to be dedicated to the public regardless of whether such disclosure is explicitly recited in the claims.

The scope of the present invention, therefore, is not intended to be limited to the exemplary embodiments shown and described herein. Rather, the scope and spirit of present invention is embodied by the appended claims. In the claims, 35 U.S.C. § 112(f) or 35 U.S.C. § 112(6) is expressly defined as being invoked for a limitation in the claim only when the exact phrase “means for” or the exact phrase “step for” is recited at the beginning of such limitation in the claim; if such exact phrase is not used in a limitation in the claim, then 35 U.S.C. § 112 (f) or 35 U.S.C. § 112(6) is not invoked.

1. A baseline restoration circuit, the circuit comprising:
an input module for receiving a signal from a sensor;
an amplifier module, operably connected to the input module, for modifying the input signal;
a baseline restoration module, operably connected to the amplifier module, for extracting a direct current component of the input signal; and
an output module, operably connected to the amplifier module, for transmitting a baseline restored signal, wherein the output module comprises differential outputs.

2. The circuit according to claim 1, wherein the circuit is configured to subtract a direct current component of the input signal that varies slowly over time relative to a duration of the input signal.

3. The circuit according to claim 2, wherein the direct current component of the input signal varies slowly over time in part based on a temperature of the sensor generating the input signal.

4. The circuit according to claim 1, wherein the circuit is configured to receive input signals corresponding to a plurality of events and to separate signals corresponding to each event in time.

5. The circuit according to claim 4, wherein the circuit is configured so that a high-pass cutoff frequency of the circuit is below 1 Hz.

6. The circuit according to claim 1, wherein the output module comprises a first differential output and a second differential output.

7. The circuit according to claim 6, wherein a difference between signals on the first and second differential outputs comprises the baseline restored signal.

8. The circuit according to claim 7, wherein the difference between signals comprises a voltage difference between the first and second differential outputs.

9. The circuit according to claim 1, wherein the circuit is configured so that the differential outputs reduce sensitivity to low-frequency noise.

10-15. (canceled)

16. The circuit according to claim 1, wherein the output module is configured to absorb reflections of signals transmitted at the differential outputs.

17. (canceled)

18. The circuit according to claim 1, wherein the circuit is configured to be located at proximity of the sensor.

19-20. (canceled)

21. The circuit according to claim 1, wherein the circuit is installed on a substrate, wherein the substrate is shaped such that the substrate is located proximally with the sensor.

22. (canceled)

23. The circuit according to claim 1, wherein the sensor is a light detector.

24. (canceled)

25. The circuit according to claim 1, wherein the amplifier module comprises a first amplifier with differential amplifier outputs.

26. (canceled)

27. The circuit according to claim 1, wherein the baseline restoration module comprises a filter network operably connected to the differential amplifier outputs.

28-37. (canceled)

38. The circuit according to claim 1, wherein the baseline restoration network comprises a switch to disengage the filter network from the circuit.

39. The circuit according to claim 1, wherein the input module is configured to transform the input signal received from the sensor.

40-42. (canceled)

43. The circuit according to claim 1, wherein the circuit is an analog circuit.

44. The circuit according to claim 1, wherein the circuit is a circuit of a light detection system.

45. The circuit according to claim 44, wherein the circuit is a circuit of a light detection system of a flow cytometer.

46-90. (canceled)
